(19) United States
(12) Patent Application Publication
(10) Pub. No.: US 2009/0169871 A1
(43) Pub. Date: Jul. 2, 2009

(54) Method for Producing High-Quality Surfaces and a Product Having a High-Quality Surface

(76) Inventors: Reijo Lappalainen, Hiltulanlahti (FI); Vesa Myllymaki, Helsinki (FI); Lasse Pulli, Helsinki (FI); Juha Makitalo, Tammisaari (FI)

Correspondence Address: BIRCH STEWART KOLASCH & BIRCH, PO BOX 747, FALLS CHURCH, VA, 22040-0747, US

(21) Appl. No.: 12/224,316

(22) PCT Filed: Feb. 23, 2007
(86) PCT No.: PCT/FI2007/000046

§ 371 Date: Jan. 15, 2009

(30) Foreign Application Priority Data
Feb. 23, 2006 (FI) 20060177

(51) Int. Cl. C23C 14/28

(52) U.S. Cl. 428/332; 427/596

(57) ABSTRACT

The invention relates to a laser ablation method for coating an object with one or more surfaces, so that the object to be coated, i.e. the substrate, is coated by ablating the target, so that the uniformity of the surface deposited on the object to be coated is ±100 nm. The surface of the coated object is advantageously free of micron size particles, and it is typically a nano technological surface where the size of separate particles is ±25 nm at most. The object also relates to products made by said method.

### FIELD OF THE INVENTION

The present invention relates to a coating method based on laser ablation for producing high-quality surfaces, as well as to a product having a high-quality surface. The invention enables an economical manufacturing of high-quality surfaces as well as a product having a high-quality surface. The invention makes it possible to economically produce high-quality surfaces for a large number of different products with different coating materials, and hence with different features.

### PRIOR ART

Laser technology has advanced significantly in the recent years and now it is possible to produce fiber-based semiconductor laser systems with a tolerable efficiency that can be used in cold ablation, for example. Among these lasers meant for cold work are picosecond lasers and femtosecond lasers. For instance in picosecond lasers, the cold work range refers to pulse lengths where the pulse length is 100 picoseconds or less. In addition to pulse length, picosecond lasers differ from femtosecond lasers with respect to the repetition frequency; the repetition frequencies of latest commercial picosecond lasers are 1-4 MHz, whereas femtosecond lasers remain in the repetition frequencies measured in kiloherzes. Cold ablation enables the vaporization of material, at best so that heat transfers are not directed to the material to be vaporized (ablated) itself, i.e. only pulse energy is directed to the material ablated by each pulse alone.

Competing with the fully fiber based diode pumped semiconductor laser, there is the lamp pumped laser source in which the laser beam is first conducted into the fiber and thence further to the work spot. According to the information available to the applicant on the priority date of the present application, these fiber based laser systems are at the moment the only way to bring about laser ablation based production on an industrial scale.

The fibers of current fiber lasers, and thereby the low-remaining beam power, cause restrictions as regards which materials can be vaporized. Aluminum can be vaporized as such with a moderate pulse power, whereas materials that are more difficult to vaporize, such as copper, tungsten etc., require a remarkably higher pulse power.

Another drawback with prior art technique is the scanning width of the laser beam. In general, there has been applied linear scanning in mirror film scanners, in which case it is theoretically possible to reach for example the nominal scan line width of roughly 70 mm, but in practice the scanning width can problematically remain even at roughly 30 mm, in which case the fringes of the scanning range can remain non-homogeneous in quality, and/or different than the central areas. Thus small scanning widths also in this sense make the use of current laser equipment in the coating applications of large, wide objects industrially unprofitable or technically impossible to realize.

As far as the applicant is aware, on the priority date of the present application, the effective capacity with known equipment remains roughly at 10 W in ablation. Now for instance the repetition frequency can be restricted to only 4 MHz pulse frequency with the laser. In case the pulse frequency should be attempted to be raised even higher, prior art scanners result in that a fairly significant share of the laser beam pulses are directed uncontrollably, on one hand to the wall structures of the laser apparatus, but also to the ablated matter in plasma form, and as a net effect, the quality of both the surface deposited by the ablated matter and the production speed are reduced, and the radiation flux hitting the target is not sufficiently uniform, which can be seen in the structure of the created plasma, which now may, when hitting the surface to be coated, form a surface with a non-homogeneous quality. The problems become worse in proportion to the growth of the plasma plume to be created.

Production speed is directly proportional to pulse repetition frequency. On the other hand, with the known reciprocating mirror film scanners, the motion keeps stopping. Because this type of mirror film scanner must, in addition to the stops, both decelerate and accelerate prior to a new deceleration and a stop—and simultaneously a change in direction; when aiming at a rise in the production speed by raising the repetition frequency, the raising of the pulse frequency results in an uneven pulse feed in the target, and thus the target material is worn unevenly, particularly in the vicinity of the stopping locations, i.e. at the fringes of the scanning range, in relation to the wearing of the area left in between the stopping locations. Likewise the plasma production, and hence also the quality of the coating that should be created thereby, can be remarkably and harmfully uneven with respect to applications where a uniform quality is required of the coating. In addition, an uneven wearing of the target can in some cases result in the formation of particle-like fragments, which first of all in machining applications weakens the quality of the machining result, which becomes rough, but also the structure in the immediate vicinity of the machining spot can be turned in an unfavorable direction.

In addition, the reciprocating motion of a mirror film scanner creates inertial forces that variably burden the structure of the mirror film scanner and bring looseness in the fastening arrangements, which means that the structure in the course of time in a way starts to drift, particularly if the operation of the mirror film scanner that keeps stopping is carried out at the extremes of its settings. In that case the inertial forces in fact also restrict the motion of the mirror film scanners, the speed of its operation. The stopping of a stalling mirror film scanner also restricts an area in the operational cycle in which the motion can be considered even and suitable for producing the plasma that is ablated from the targets. In that case the operational cycle remains in a way lacking, and only part thereof can be used at an effective capacity, even if the operation were already fairly slow. Now the only result from the stalling mirror film scanners is a remarkably slow plasma production, instability in the long run but also particle-like emissions into the plasma, which emissions are visible both on the surfaces of the machined object and/or of the targets, as well as in the coating quality of the objects to be coated. The effective scan line width on the target surface can also remain remarkably short.

In prior art arrangements, problems are also caused by a change in the focus of the laser beam in the middle of ablation, relative to the material to be vaporized, which immediately affects the quality of the plasma, because the energy density of the pulse on the surface of the material will (normally) decrease, whereby vaporization/plasma generation is no longer complete. This results in low-energy plasma and unnecessarily large amounts of fragments/particles as well as a change in the surface morphology, and possible changes in the adhesion of the coating and/or coating thickness.

The significant development in laser technology in the recent years has brought means to be used in high-power laser systems that are based on semiconductor fibers and therefore support the development of methods based on cold ablation.

However, the fibers in conventional fiber lasers do not allow high-power usage, where pulse-shaped laser radiation is transmitted along the fibers to the work spot, at a sufficient net power level. At the power level required in the work spot, regular fibers cannot withstand the transmission loss created therein by absorption. One of the reasons to use fiber technology in laser beam transmission from the source to the target has been that the propagation of even a single laser beam through free air space constitutes a considerable safety risk for the workers in an industrial work environment, and on an industrial scale it is technically very challenging, if not outright impossible.

On the priority date of the present application, fully fiber based diode pumped semiconductor lasers compete with lamp pumped lasers, in which case both have a feature according to which the laser beam is first conducted into the fiber, and thence further to the work spot target. These fiber based laser systems are the only way to bring about laser ablation based production on an industrial scale.

The present-day fibers in fiber lasers and, hence, the limited beam power imposing limitations as to which fiber materials can be used in the vaporization/ablation of target materials. Aluminum can be vaporized/ablated by low-power pulses, whereas materials more difficult to vaporize/ablate, such as copper, tungsten etc., require a considerably higher pulse power. This also applies in situations where there is an interest to produce new compounds by the same know technique. Among a few examples, let us point out the production of diamond directly from carbon, or the production of aluminum oxide directly from aluminum and oxygen, through an appropriate gas phase reaction in the conditions after laser ablation.

On the other hand, one of the most prominent obstacles for further development in the fiber laser technique seems to be the resistance of the fiber to high-power laser pulses, so that the fiber does not break and the laser beam quality does not suffer.

When applying the new cold ablation for solving problems related to both quality and production rate problems connected to coatings, thin film production as well as to cutting/embossing/engraving etc., the central approach has been to try and increase the laser power and to reduce the laser beam spot size on the target surface. However, a large share of the power were consumed in noise. Qualitative problems and problems connected to production speed were left unsolved, even if some laser manufacturers did solve problems connected to the laser efficiency. The production of representative samples of both, i.e. coatings/thin films as well as cutting/embossing/engraving etc. has only been possible at a low repetition frequency, with a narrow scanning width and a long work time, which features as such fall outside industrial feasibility, and the fact is particularly emphasized in the case of large objects.

Owing to the pulse energy content, when the pulse power increases while the pulse duration is simultaneously reduced, this problem becomes more significant, when observing laser pulses that are shorter in duration. Problems occur remarkably often even with nanosecond pulse lasers, although they are not as such suitable for cold ablation methods.

If the pulse duration is reduced to the femto or attosecond scale renders the problem nearly unsolved. For instance a picosecond laser system, where the pulse duration is 10-15 ps, the pulse energy must be 5 μJ 10-30 μm for a spot size, when the total power in the laser is 100 W and the repetition frequency is 20 MHz. According to the information obtained by the applicant, a fiber that withstands this kind of pulse power is not available on the priority date of the present application.

The shorter the pulse, the higher the energy per a given period of time to be conducted along the fiber and therethrough, via a given cross-section. In the above described conditions, with respect to the pulse duration and laser power, the level of an individual pulse can correspond to the power of roughly 400 kW. The manufacturing of a fiber that could withstand even 200 kW and could allow a 15 ps pulse to go through without distortions in the shape of an optimum pulse has not yet been possible, as far as the applicant knows, before the priority date of the present application.

If the aim is not to restrict the possibilities for plasma production from any available material, the pulse power level must be selected freely, for instance between 200 kW and 80 MW. Problems with the restrictions of current fiber lasers are not caused by the fiber only, but are also related to the interconnecting of separate diode pumped lasers by intermediation of optical couplers when aiming at a desired type of total power. This kind of combined beam has in a single fiber been conducted to the work spot by conventional technique.

As a consequence, optical couplers should withstand at least as much power as the fibers themselves, when used on the transmission bus for transmitting high-power pulses to the work spot. Even when using regular power levels, the manufacturing of suitable optical couplers is extremely expensive, the operation is in a sense insecure and the couplers are worn out in use, which means that they must be replaced within a given period of time.

The production rate is directly proportional to the repetition frequency or rate. On the other hand, with known mirror film scanners (i.e. galvanic scanners or other scanners of the corresponding reciprocating type), featuring a reciprocating swinging motion typical of their operation cycle, the stopping of the mirror at both ends of the operation cycle is fairly problematic, as are the acceleration and deceleration connected to the turning point and to the connected momentary stopping, which affect the feasibility of this kind of a mirror as a scanner, but particularly also affect in the scanning width. If the production scale should be increased by raising the repetition frequency, the accelerations and decelerations result either in a narrowed scanning range, or in an uneven distribution of the radiation, and thus also of the plasma in the target, when the radiation hits the target through the mirror that is decelerating and/or accelerating.

If the coating/thin film production speed is attempted to be raised simply by raising the pulse repetition frequency, the above mentioned known scanners direct pulses to overlapping spots in the target are, at the already low pulse frequencies in the kHz range in a way that cannot be controlled in advance.

The same problem also applies to nanosecond range lasers, but here the problem is even more serious, because the pulses are high in energy and long in duration. Therefore even a single pulse in the nanosecond range results in a serious erosion in the target material.

In known techniques, it is possible that target is not only unevenly consumed, but it may also be easily fragmented, which weakens the plasma quality. Therefore a surface to be coated by the described technique also suffers from harmful problems brought along by the plasma. The surface may contain fragments, and the plasma can be distributed unevenly, hence also forming a fragmented surface etc., which are problematic issues in applications requiring accuracy, but are not necessarily problematic for instance in paint or pigment applications, where the disadvantages do not surpass the application specific observation threshold. The current methods use the target only once, which means that the same target cannot be reused on the same surface. It has been attempted to solve this problem by using only a virginal target surface, and by moving the target and/or the beam spot appropriately in relation to each other.

In machining or working type applications, any waste or leftovers containing fragments can also result in an uneven cutting line, which consequently is not acceptable, as could happen in cases dealing with drillings connected to flow control. Surfaces can also obtain an uneven appearance owing to the released fragments, which is not appropriate for example in the production of certain semiconductors.

Moreover, the reciprocating motion of mirror film scanners causes inertial forces that burden the structure itself, but also locations where this kind of mirror is attached by bearings for moving said mirror. The described inertial force can gradually bring looseness to the fastening arrangements of the mirror, particularly if the mirror would function in the extreme range of its settings, and it can result in the drifting of the settings in the long run, which can be seen in an uneven reproducibility of the product quality. Owing to the stoppings as well as to the changes in direction and speed in motion, this kind of mirror film scanner also has a very restricted scanning width to be applied in ablation and in the production of plasma. The effective production cycle in relation to the total length of the production cycle is short, even if the operation were slow in any case. From the point of view that aims at increasing the production, a system that uses mirror film scanners is inevitably slow with respect to plasma production, it has a narrow scanning width, it is instable in the long run and has a high probability to collide with harmful particle emissions in the plasma, in which case the resulting machining and/or coating products also obtain the corresponding features as a consequence.

Fiber laser technology also associates with other problems; for example, large amounts of energy cannot be transmitted through optical fiber without the fiber melting and/or breaking or without a substantial degradation of the laser beam quality as the fiber becomes deformed due to the high power transmitted. Already a pulse power of 10 μJ may damage the fiber if it has even the slightest structural or qualitative weaknesses. In fiber technology, the elements especially prone to damage are the fiber optic couplers, which, for example, connect together a plurality of power sources, such as diode pumps.

The shorter the pulse, the bigger the amount of energy in it, which means that this problem becomes more emphasized as the laser pulse gets shorter for transmitting the same amount of energy. In nanosecond pulse lasers, the problem is especially remarkable.

As the pulse duration is shortened, down the scale of the femtosecond or even attosecond, the problem becomes nearly impossible to solve. For example, a picosecond in a laser system where the pulse duration is 10-15 ps, the pulse energy should be 5 μJ 10-30 μm per spot, when the total power in the laser is 100 W, and the repetition frequency is 20 MHz. On the priority date of the present application, the applicant is not aware of a fiber that could withstand this kind of a pulse.

In laser ablation, which is an important field of application for the fiber laser, it is, however, quite important to achieve a maximal and optimal pulse power and pulse energy. Considering a situation where the pulse length is 15 ps, the pulse energy is 5 μJ and the total power is 1000 W, the energy level of the pulse is about 400,000 W (400 kW). According to the information available to the applicant on the priority date of the application, no-one has succeeded in manufacturing a fiber which would transmit even a 200-kW pulse with a 15-ps pulse length, so that the pulse would still remain optimal and with the pulse shape remaining optimal.

In any case, when aiming at unrestricted possibilities in plasma production from any available material, the power level for the pulses should be selected fairly freely, for example between 200 kW and 80 MW.

However, the problems associated with present-day fiber lasers are not solely limited to the fiber, but also to the coupling of separate diode pumps by means of optical couplers in order to achieve a desired total power, so that the resulting beam could be conducted through one single fiber to the work spot.

The applicable optical couplers also should withstand as much power as the optical fiber that carries the high power pulse to the work spot. In addition, the pulse shape should remain optimal in all stages of transmission of the laser beam. Optical couplers that withstand even the current power values are extremely expensive to manufacture, they have rather a poor reliability, and they constitute an element susceptible to wear, which requires periodic replacing.

Prior art techniques that are based on laser beams and ablation involve problems relating to power and quality, for example and especially in association with scanners, whereby, from the point of view of ablation, the repetition frequency cannot be raised to a level that would enable a large-scale mass production of a product of good and homogeneous quality. In addition, prior art scanners are located outside the vaporizer unit (vacuum chamber) so that the laser beam has to be directed into the vacuum chamber through an optical window which will always reduce the power to some extent.

According to the information available to the applicant, the effective power in ablation, when using equipment known on the priority date of the present application, is around 10 W. Then also the repetition frequency, for instance, may be limited to only a 4-MHz chopping frequency with laser. If one attempts to increase the pulse frequency further, the scanners according to the prior art will cause a significant part of the pulses of the laser beam being directed uncontrollably onto the wall structures of the laser apparatus, and also into the ablated material in the form of plasma, having the net effect that the quality of the surface to be produced will suffer as will also the production rate. Furthermore, the radiation flux hitting the target will not be uniform enough, which can affect the structure of the plasma and hence may, upon hitting the surface to be coated, produce a surface of uneven quality.

Then, also in machining applications, where the target is an object and/or a part thereof to be machined, the surface of which should be shaped, it easily happens that both the cutting efficiency and the quality of the cut are affected. Furthermore, there is a significant risk of fragments and spatters landing on the surfaces around the point of cut as well as on the very surface to be coated. In addition, with prior art technology, it takes time to apply several layers with repeated surface treatment, and the quality of the end result is not necessarily uniform enough.

With known scanners of which the applicant is aware on the priority date of the present application the scanning speeds remain at about 3 m/s, and even then, the scanning speed is not really constant but varies during the scanning. This is mainly due to the fact that scanners according to the prior art are based on turning mirrors that stop when the scanning distance has been traveled, and then move in the opposite direction, repeating the scanning procedure. Reciprocating mirrors are also known, but these have the same problem with the non-uniformity of the movement. An ablation technique implemented with planar mirrors is disclosed in the patent publications U.S. Pat. No. 6,372,103 and U.S. Pat. No. 6,063,455. Since the scanning speed is not constant, due to the acceleration, deceleration and stopping of the scanning speed, also the yield of plasma generated through vaporization at the work spot is different at different points of the target, especially at the extremities of the scanning area, because the yield and also the quality of the plasma completely depend on the scanning speed. In a sense, one could consider it as a main rule that the higher the energy level and the number of pulses per time unit, the bigger this drawback when using prior art devices. In successful ablation, matter is vaporized into atomic particles. But when disturbances occur, the target material will be released/become detached in fragments that may be several micrometers in size, which naturally affects the quality of the surface to be produced by ablation.

Since the present-day scanner speeds are low, increasing the pulse frequency would result in energy levels so high being directed onto the mirror structures that present-day mirror structures would melt/burn if the laser beam were not expanded prior to its arrival at the scanner. Therefore, a separate collecting lens arrangement is additionally needed between the scanner and the ablation target.

The operating principle of present-day scanners dictates that they have to be light. This also means that they have a relatively small mass to absorb the energy of the laser beam. This fact further adds to the melting/burning risk in present ablation applications.

One problem in prior-art solutions is the scanning width. These solutions use line scanning in mirror film scanners whereby, theoretically, one could think that it is possible to achieve a nominal scan line width of about 70 mm, but in practice the scanning width may problematically remain even around 30 mm, whereby the fringe regions of the scanning area may be left non-uniform in quality and/or different from the central regions. Scanning widths this small also contribute to the fact that the use of present-day laser equipment in surface treatment applications for large and wide objects is industrially unfeasible or technically impossible to implement.

If there occurs a situation in accordance with the prior art, where the laser beam is out of focus, the resulting plasma may have rather a low quality. The plasma that is released may also contain fragments of the target. At the same time, the target material to be vaporized may be damaged to such an extent that it cannot be used anymore. This situation is typical in the prior art when using as the material source a target that is too thick. In order to keep the focus optimal, the target should be moved in the direction of incidence of the laser beam, for a distance equivalent to the extent to which the target is consumed. The problem, however, remains unsolved—i.e. even if the target could be brought back into focus, its surface structure and composition may already have changed, the extent of the change being proportional to the amount of material vaporized off the target. The surface structure of a thick target according to the prior art will also change as it wears. For instance, if the target is a compound or an alloy, it is easy to see the problem.

In arrangements according to the prior art, a change in the focus of the laser beam in the middle of ablation, relative to the material to be vaporized, will immediately affect the quality of the plasma, because the energy density of the pulse on the surface of the material will normally decrease, whereby the vaporization/generation of plasma is no longer complete. This results in low-energy plasma and unnecessarily large amounts of fragments/particles as well as a change in the surface morphology, and possible changes in the adhesion of the coating and/or coating thickness.

Attempts have been made to alleviate the problem by adjusting the focus. When in equipment according to the prior art the repetition frequency of the laser pulses is low, for instance below 200 kHz, and the scanning speed only 3 m/s or less, the speed of change of the intensity of plasma is low, whereby the equipment has time to react to the change of the intensity of plasma by adjusting the focus. A so-called real-time plasma intensity measurement system can be used when a) the quality of the surface and its uniformity are of no importance or b) when the scanning speed is low.

Consequently, according to the information available to the applicant on the priority date of the present application, it is not possible to produce high-quality plasma using prior-art technology. Thus quite many coatings cannot be manufactured as high-quality products in accordance with the prior art.

Systems according to the prior art require complex adjustment systems which must be used in them. In current known methods the target is usually in the form of a thick bar or sheet. A zoom focusing lens must be used or the target must be moved toward the laser beam as the target gets consumed. Even an attempt to implement this practice is already extremely difficult and expensive, if at all possible in a manner sufficiently reliable, and even then the quality varies greatly, whereby precise control is nearly impossible, the manufacture of a thick target is expensive and so on.

The US publication teaches how the current prior art technology can direct the laser pulse to the ablation target only as either predominately S polarized or, alternatively, predominately P polarized or circularly polarized light, but not as random polarized light.

### GENERAL DESCRIPTION OF THE INVENTION

Current coating methods based on laser ablation or other competing methods do not allow the manufacturing of surfaces, where the surface uniformity would be good also on the nano technological scale. Apart from the fact that the surfaces are not uniform, they are typically always covered by micron size particles, either as having partly penetrated the coating surface, or then on top of said surface. The non-uniform quality of the surface along or together with said particles deteriorates or completely spoils for example the optical quality (transparence) of the surface, weakens the friction features of said surface and often also weakens the adhesion of the created surface to the substrate to be coated.

The industrial production of hard, scratch-free surfaces has been long expected, even if for example diamond coatings have already been applied for roughly 50 years. Even today, this is understood as DLC films (Diamond Like Carbon), the maximum temperature of usage is 200° C., which is moderately soft and is poor (black) in optical features already in the thickness of one micron.

In case some kind of surface is achieved, it is often easily detached from the substrate surface. The thickness of the created surface is difficult to adjust. The coating of three-dimensional objects is nearly impossible, and if it succeeds, it is at least extremely slow and, owing to high production expenses, impossible to realize industrially. The generation of 3D objects has been even technically impossible.

The manufacturing of sapphire surfaces (monocrystalline aluminum oxide) for example on top of small-size lenses is still impossible for the prior art, even if it would offer an excellent solution, both optically and because of its hardness features, for many other purposes, too.

The present invention relates to a laser ablation method for coating an object with one or several surfaces, wherein the object to be coated, i.e. the substrate, is coated by ablating the target, so that the uniformity of the surface created in the object to be coated is +100 nm. In addition, the quality of the surfaces of the objects manufactured according to the method of the invention are typically such that they do not contain any particles of the micro size (>1 μm), and advantageously the created surfaces do not contain any particles with a size more than 100 nm. Optimally the created surfaces do not include particles with a size more than 25 nm. These kind of surfaces have excellent optical features, a uniform quality and other features that are required at each time.

The present invention enables the manufacturing of any planar or three-dimensional surface or even a 3D object with a high quality, economically and industrially feasibly.

In addition, the present invention relates to an object, coated by the laser ablation method with one or several surfaces, where said object, i.e. the substrate, is coated by ablating the target so that the uniformity of the surface deposited on the coated object is ±100 nm.

The present invention is based on the surprising observation that both planar and three-dimensional geometric objects can be coated with excellent technical features (surface uniformity, coarseness features, hardness and when needed, also optical features and hardness) and industrially feasible production rates.

According to the prior art, the distance between the target material to be ablated and the substrate to be coated is typically roughly 30 mm-70 mm, but now there was also made the surprising observation that the same technically high-quality surfaces can according to the invention be manufactured with very short distances between the target and the substrate, i.e. distances within the range 2 μm-10 mm. In connection with the invention, there was also found out that there are products that can be coated with desired results only at said short distances.

Moreover, it was found out that the same technically high-quality surfaces can according to the invention also be manufactured in low vacuums or at certain conditions even in a gas atmosphere with a normal air pressure. This naturally drops the production expenses dramatically in the form of reduced equipment requirements (good vacuum chambers) as well as in an increased speed in the implementation of products. Earlier the coating of some objects, particularly large objects, by laser ablation would have been impossible to realize economically exactly because for large-size objects it would have been necessary to build so large and slowly pumped vacuum chambers that the production would not be economically profitable. In addition, with some products, such as stone materials containing crystal water, even high vacuums cannot be used without this vacuum space causing, particularly together with raised temperatures, the breaking up of the crystal water contained in the stone, and simultaneously the breaking of the structure of the stone product.

The production speed of a surface according to the invention is immense in comparison with the prior art production speed. When the production of one carat (0.2 g) diamond by prior art methods takes 24 hours, the current method produces for instance four carats (0.8 g) per hour with the laser power of 20 watts. According to the invention, it was found out that the quality features of the desired material, for example diamond, can be adjusted according to the needs in each case.

It is an aim of the invention to introduce a surface treatment apparatus, by which problems connected to the prior art technique can be solved or at least alleviated. Another aim of the invention is to introduce a method, apparatus and/or arrangement for coating the target to be coated more efficiently and with a higher-quality surface than what is known in the prior art at the priority date of the present application. Yet another aim of the invention is to set forth a three-dimensional printing unit, to be realized by a technique where the surface treatment apparatus is used for coating an object repeatedly and with a better surface than is known in the prior art at the priority date of the present application. The aims of the invention are connected to the following objects enlisted below as follows:

It is a first object of the invention to achieve at least a novel method and/or means connected thereto for solving the problem how to produce fine, high-quality plasma in practice of whichever target, so that the target material does not form any fragments at all in the plasma, i.e. the plasma is pure, or said fragments, in case they exist, occur only scarcely and are smaller in size than the ablation depth, from where said plasma is produced by ablating said target.

A second object of the invention is to achieve at least a novel method and/or connected means for solving the problem how, by releasing high-quality plasma, there can be produced a fine and uniform cutting line to be utilized in a cold work method that removes material from a target as far as the ablation depth, so that the target to be worked does not form any fragments that could be mixed in the plasma, in other words the plasma is pure, or said fragments, in case they exist, occur only scarcely and are smaller in size than said ablation depth, from where said plasma is produced by ablating said target.

A third object of the invention is to achieve at least a novel method and/or connected means for solving the problem how to coat the surface of an area serving as a substrate by using high-quality plasma that does not contain any particle-like fragments at all, in other words when the plasma is pure, or when said fragments, in case they exist, occur only scarcely and are then smaller in size than said ablation depth from where said plasma is produced by ablating said target, in other words how to coat the substrate surface by using pure plasma that can be produced practically from any material.

A fourth object of the invention is to achieve at least a novel method and/or connected means for solving the problem how to create by means of high-quality plasma a coating with good adhesion features for gripping the substrate, so that the wasting of kinetic energy in the particle-like fragments is reduced by restricting the occurrence of the fragments or by restricting their size to be smaller than the ablation depth. At the same time, owing to their absence, the fragments do not create cool surfaces that could affect the homogeneity of the plasma jet through the phenomena of nucleation and condensation. Moreover, according to the fourth object, the radiation energy is effectively transformed to plasma energy, as the area affected by heating is minimized when using advantageously short radiation pulses, in other words pulses of the picosecond order or even shorter duration, and in between the pulses, there is applied a certain interval in between two successive pulses.

A fifth object of the invention is to achieve at least a novel method and/or connected means for solving the problem how to achieve a wide scanning width simultaneously with the quality of high-quality plasma and a wide coating width for even large objects on an industrial scale.

A sixth object of the invention is to achieve at least a novel method and/or connected means for solving the problem how to achieve a high repetition frequency to be used in industrial-scale applications, in line with the above enlisted aims.

A seventh object of the invention is to achieve at least a novel method and/or connected means for solving the problem how to produce high-quality plasma for coating surfaces and manufacturing products in line with the aims from first to sixth, but still save target material to be used in the coating steps for generating recoatings/thin films of the same quality, where it is needed.

It is yet another extra object of the invention to apply such methods and means in line with said first, second, third, fourth and/or fifth aim, for solving the problem as how to cold work and/or coat surfaces, in an appropriate line with respect to each suitable type of such products.

The object of the invention is realized by generating high-quality plasma by a surface treatment apparatus based on the use of radiation, which apparatus includes, in the transmission line of the radiation emitted thereby, a turbine scanner according to an embodiment of the invention.

When using a surface treatment apparatus according to an embodiment of the invention, the removal of material from the surface to be treated and/or the generation of coating can be raised up to a level that is required of a high-quality coating, even at a sufficient production speed without unnecessary restrictions to the radiation power.

Other embodiments of the invention are by way of examples also presented in the dependent claims. Embodiments of the invention can be combined where applicable.

Embodiments of the invention can be used to make products and/or coatings where the materials of the product can be chosen rather freely. For example, semiconductor diamond can be produced, but in a manner of mass production, very large amounts, with low cost, good repeatability and in high quality.

In a group of embodiments of the invention the surface treatment is based on laser ablation, whereby it is possible to use almost any laser source as a source of radiation for the beam to transmitted in a radiation transmission line along which there is a turbine scanner. Applicable are then such laser sources as CW, semiconductor lasers, and such pulsed laser systems where the pulse length is of the order piko, femto and attosecond, said three latter pulse lengths representing lengths that are suitable for cold work methods. The source of radiation is not, however, limited in the embodiments of the invention.

### FIGURES

FIG. 1 illustrates various possible applications for the method according to the invention.

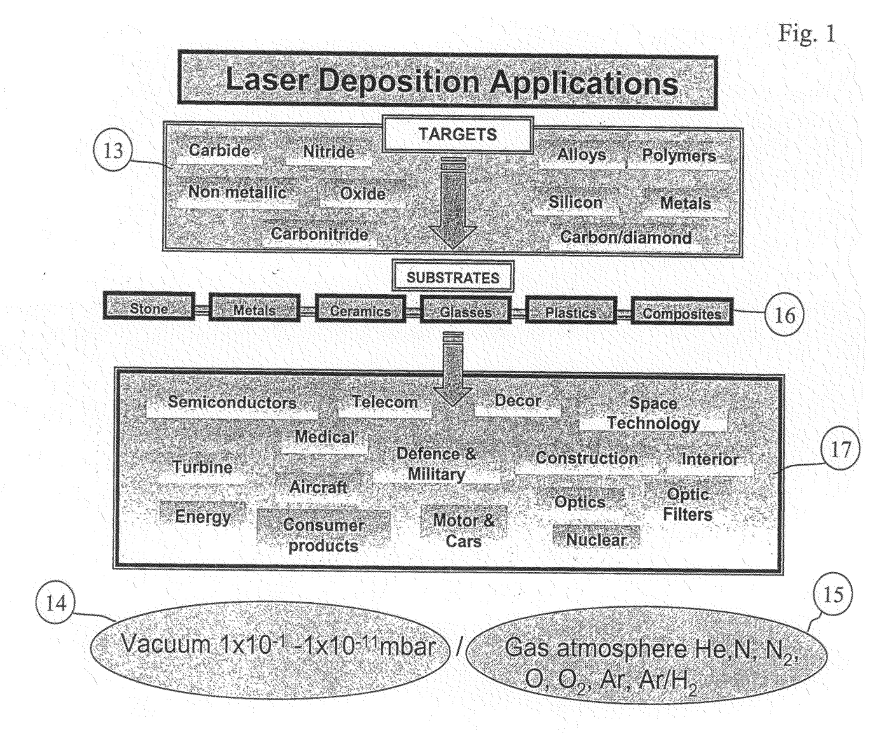

FIG. 2 illustrates an ablation coating apparatus according to an embodiment of the invention,

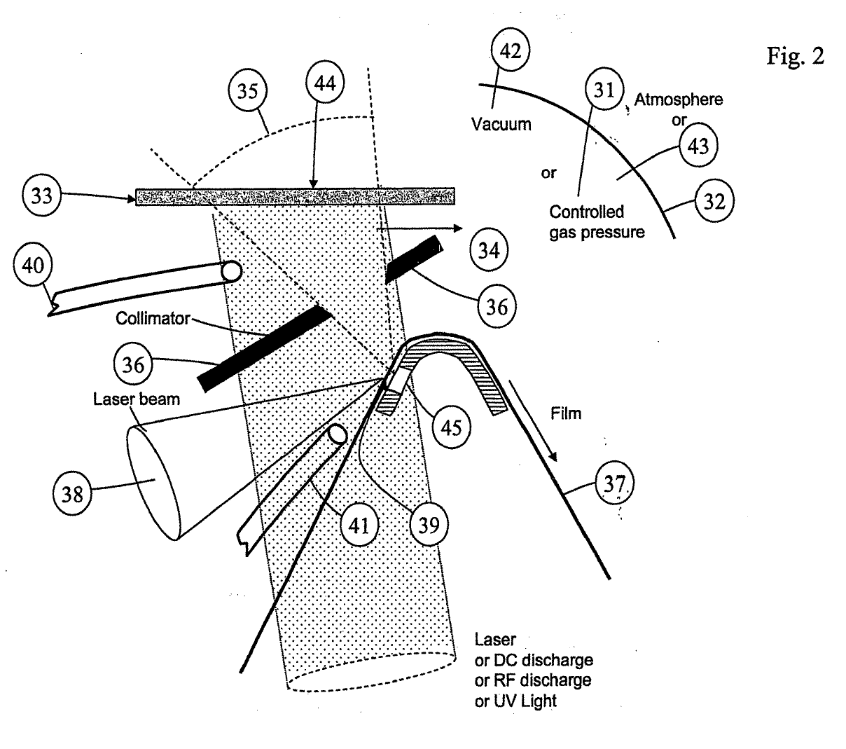

FIG. 3 illustrates a multilayer substrate, formed in an apparatus according to an embodiment of the invention,

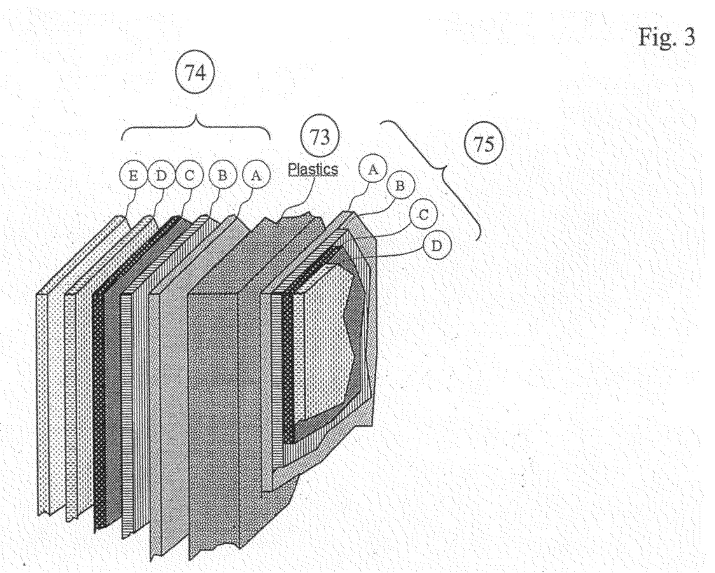

FIG. 4. illustrates an embodiment of the invention where a monocrystalline diamond beam is manufactured in a laser ablation arrangement, in which arrangement the carbon material (material preform 127) to be vaporized is pyrolytic carbon, and the distance between the target and the substrate is 4 mm,

FIG. 5. illustrates an object, coated according to the invention, with a large and three-dimensional geometry, in this case a snow pusher,

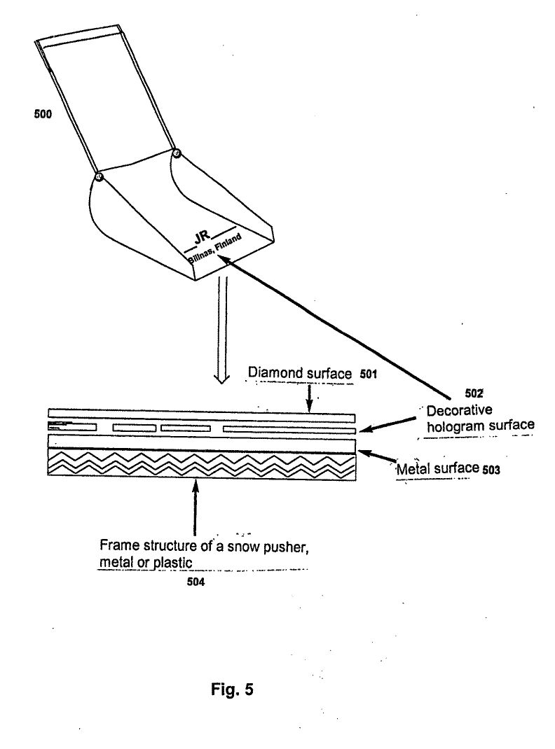

FIG. 6. illustrates a telecommunication shell structure coated according to the invention,

FIG. 7. illustrates an ablation coating apparatus according to an embodiment of the invention, where the target is fed as tape feed,

FIG. 8. illustrates a turbine scanner used in some embodiments of the invention for scanning the laser beam,

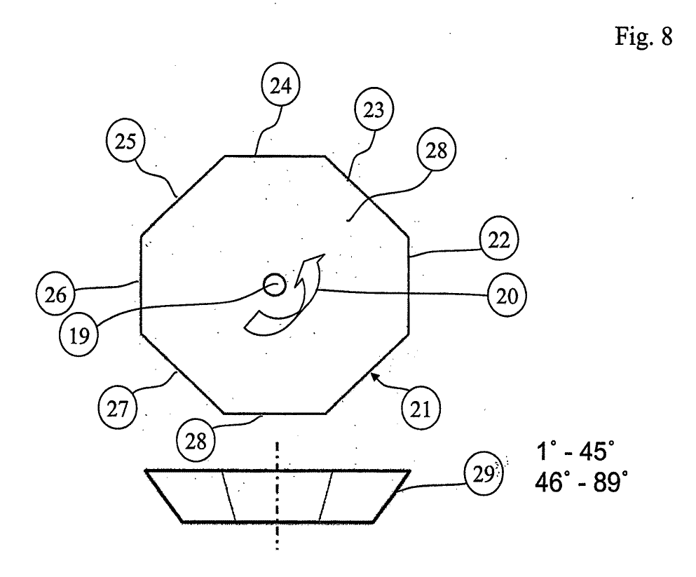

FIG. 9. illustrates the difference between hot working (micro and nanosecond pulse lasers, with long pulses) and cold work (pico and femtosecond lasers, short-pulsed) with reference to a heat transfer directed to the ablated material and to the damages caused thereby in the target material,

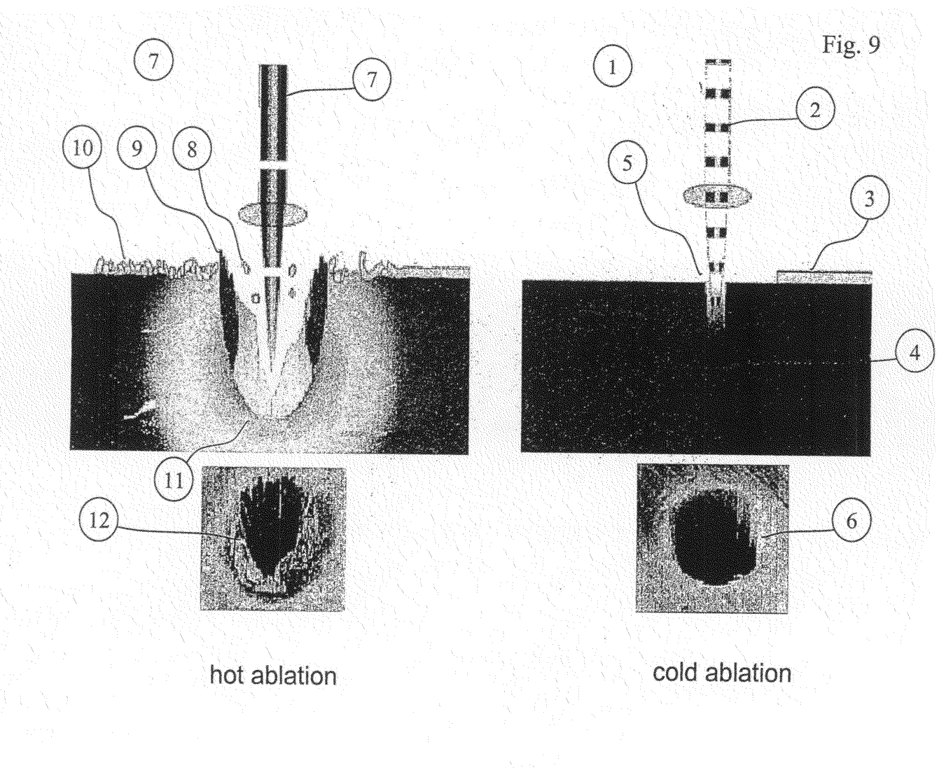

FIG. 10 illustrates embodiments according to the invention for coating stone products,

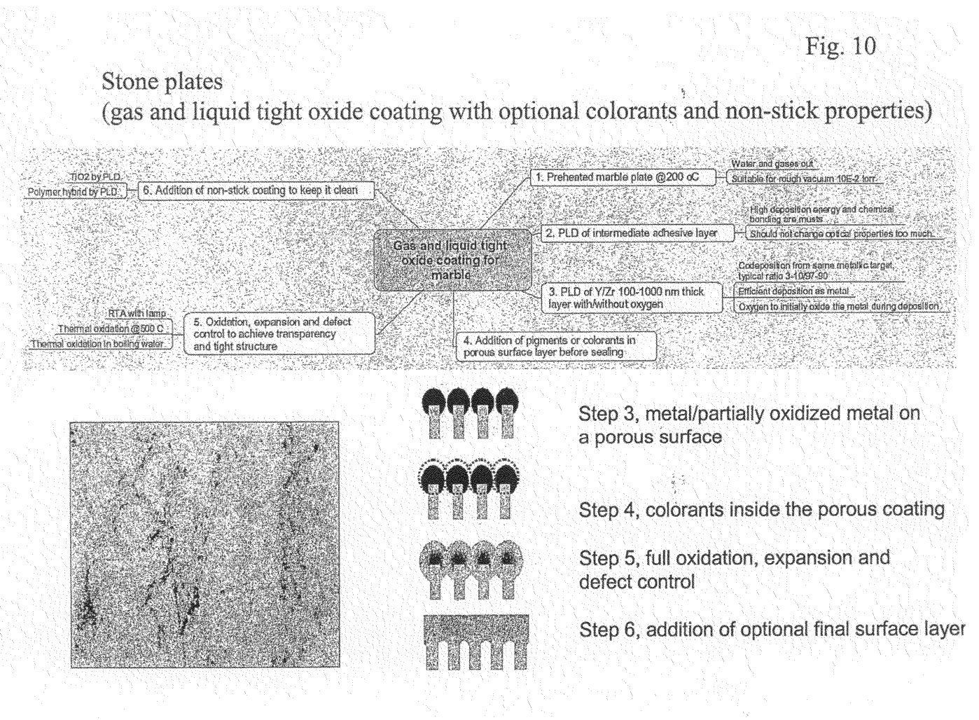

FIG. 11 illustrates medical instruments coated according to the invention,

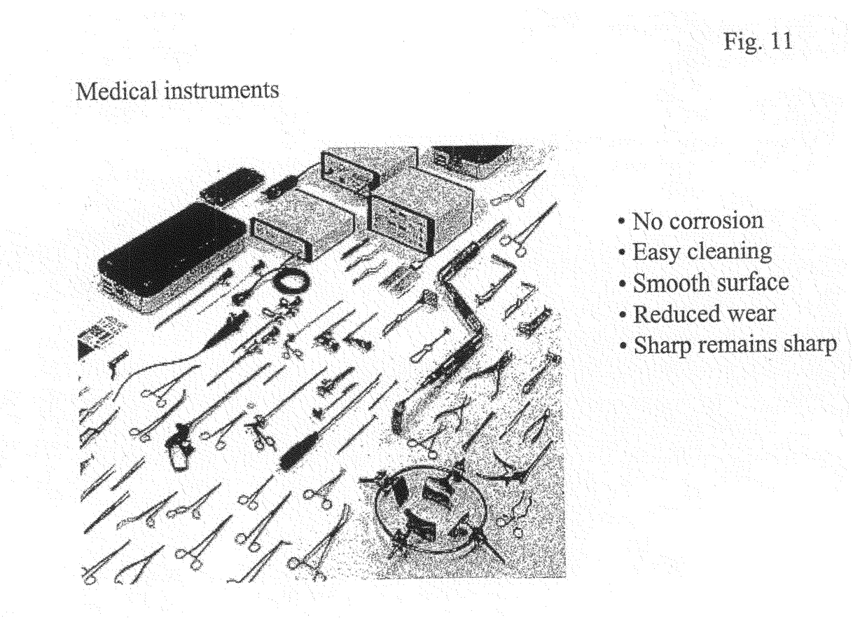

FIG. 12 illustrates medical products coated according to the invention,

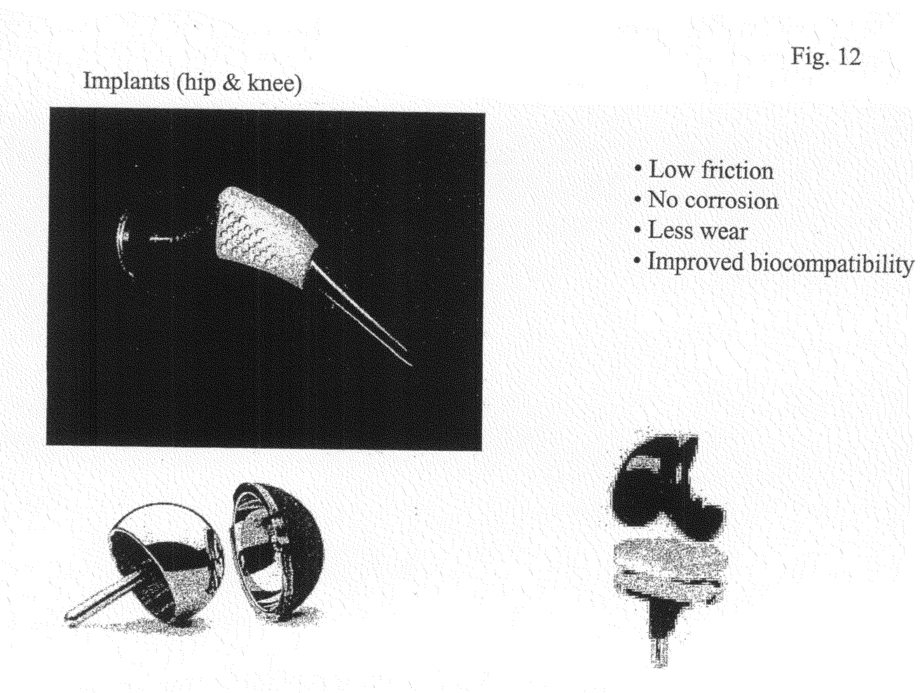

FIG. 13 illustrates airplane elements to be coated according to the invention,

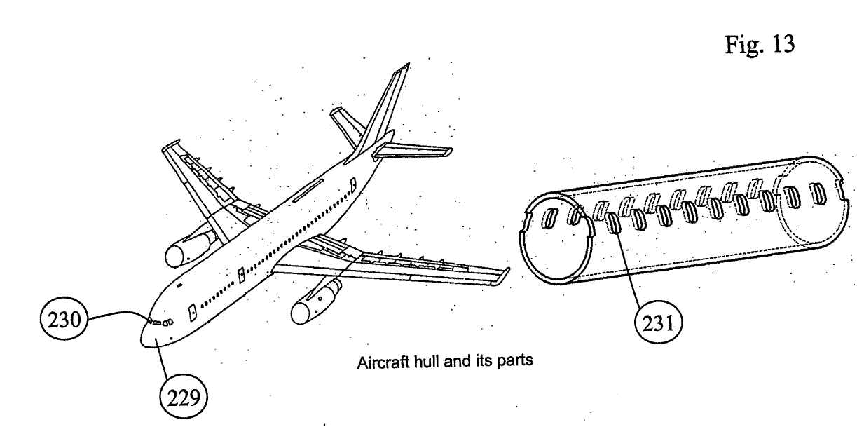

FIG. 14 illustrates optical products coated by aluminum oxide according to the invention,

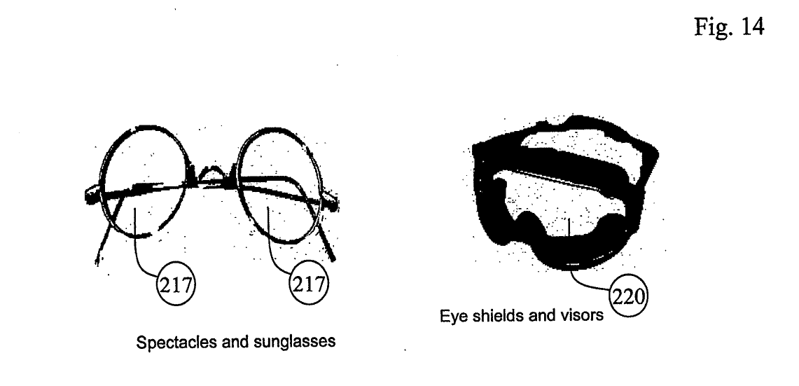

FIG. 15 illustrates coating application examples according to preferred embodiments of the invention.

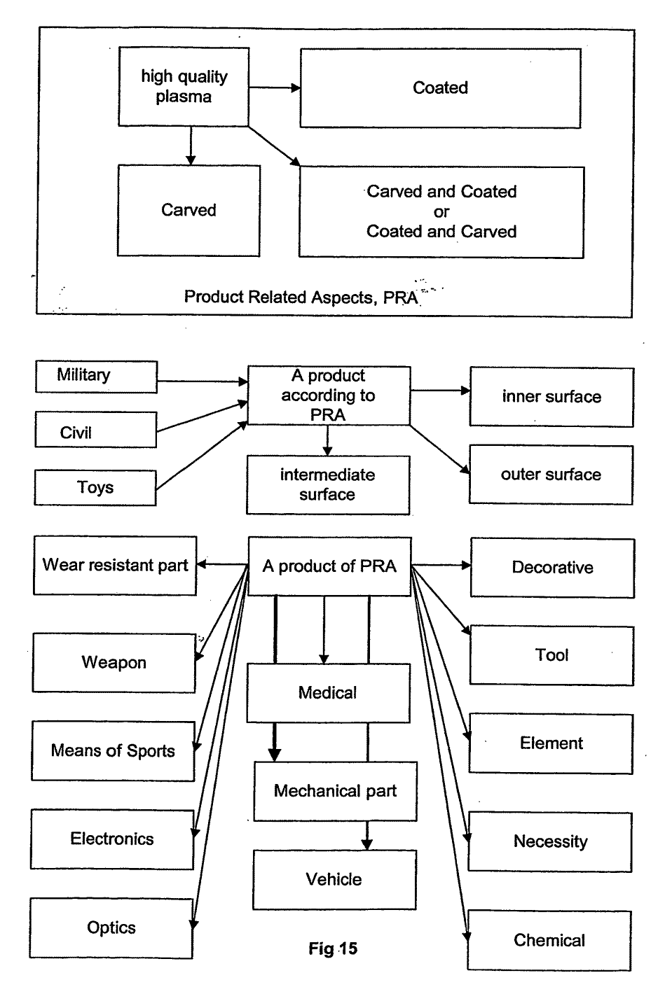

### DETAILED DESCRIPTION OF THE INVENTION

The invention relates to a laser ablation method for coating an object with one or several surfaces, wherein the object to be coated, i.e. the substrate, is coated by ablating the target, so that the uniformity of the object to be coated is ±100 nm when measured in the area of one square micrometer by an atomic force microscope (AFM).

In a preferred embodiment of the invention, the uniformity of the surface created in the object to be coated is ±25 nm, and in the most preferred embodiment of the invention, the uniformity of the surface created in the object to be coated is ±2 nm.

The uniformity of the created surface can be adjusted according to the requirements in each case.

In an embodiment of the invention, on the coated surface there are no particles with a diameter larger than 1 μm. In a preferred embodiment of the invention, on the coated surface there are no particles with a diameter larger than 100 mm. In the most preferred embodiment of the invention, on the surface coated according to the invention, there are no particles with a diameter larger than 25 nm.

In the method according to the invention, the thickness of the created surfaces is not restricted. According to the invention, objects can be coated, from 1 nm up, always so that there are formed even very thick surfaces or then 3D structures, for example.

The distance between the object to be coated, i.e. the substrate, and the material to be ablated by laser beams, i.e. the target, is according to the prior art 30 mm-70 mm, advantageously 30 mm-50 mm.

According to a preferred embodiment of the invention, the distance between the object to be coated, i.e. the substrate, and the material to be ablated by laser beams, i.e. the target, is 1 mm-10 mm. In another preferred embodiment of the invention, the distance between the substrate and the target is 2 mm-8 mm, such as 3 mm-6 mm. The required distance depends on the substrate to be coated and on the quality and/or technical features of the desired surface.

In yet another embodiment of the invention, the distance between the target and the substrate is as short as 2 μm-1 mm. With these kind of distances, there are obtained, in accordance with the invention, excellent uniform surfaces, for instance in “sharp” targets, such as needles and knives and various blade edges. The obtained surface hardness also is of an excellent quality. One embodiment of the invention are diamond coated needles, knives and blades, and particularly the tips of all these. A diamond can also be replaced by other hard coatings.

In a preferred embodiment of the method, the surface to be coated is formed of material ablated from one single target.

In another preferred embodiment of the method, the surface to be coated is deposited of material ablated simultaneously from several targets.

Further, in another preferred embodiment of the invention, the surface to be coated is formed so that in a plasma plume generated of the ablated material, there is brought reactive material that reacts with the ablated material contained in the plasma plume, and the created compound or compounds form the surface to be made on the substrate.

Consequently, when ablating a target with laser pulses, there is generated a molecular plasma plume.

For the sake of clarity, let us point out that atom level plasma also means a gas that is at least partly in an ionized state, which gas may also contain atom parts with electrons left as bound by electric forces in the nucleus. Thus for instance once ionized neon could be counted as atom level plasma. Naturally also particle groups containing electrons and pure nuclei as such, separated from each other, are counted as plasma. Thus, good plasma in pure form only contains gas, atom level plasma and/or plasma, but not for example solid fragments and/or particles.

Let it be noted about using pulses in pulsed laser deposition (PLD) applications that the longer the laser pulse in PLD, the lower the plasma energy level and atom speeds of the matter vaporized from the target as the pulse hits the target. Conversely, the shorter the pulse, the higher the energy level of the vaporized matter and the atom speeds in the jet of matter. On the other hand this also means that the plasma obtained in the vaporization is more uniform and homogeneous, without precipitations and/or condensation products, such as fragments, clusters, micro- or macro-particles, of the solid or liquid phase. In other words, the shorter the pulse and the higher the repetition frequency, provided that the ablation threshold of the material to be vaporized is exceeded, the better the quality of the plasma produced.

The effective depth of the heat pulse from a laser pulse hitting the surface of a material varies considerably between laser systems. This affected area is called the heat affected zone (HAZ). The HAZ is substantially determined by the power and duration of the laser pulse. For example, a nanosecond pulse laser system typically produces pulse powers of about 5 MJ or more, whereas a picosecond laser system produces pulse powers of 1 to 10 μJ. If the repetition frequency is the same, it is obvious that the HAZ of the pulse produced by the nanosecond laser system, with a power of over 1000 times higher, is significantly deeper than that of the picosecond pulse. Furthermore, a significantly thinner ablated layer has a direct effect on the size of particles potentially coming loose from the surface, which is an advantage in so-called cold ablation methods. Nano-sized particles usually will not cause major deposition damages, mainly holes when they hit the substrate.

In an embodiment of the invention, fragments in the solid (also liquid, if present) phase are picked out by means of an electric field. This can be achieved by using a collecting electric field and, on the other hand, by keeping the target electrically charged so that fragments moving with a lower electrical mobility can be directed away from the plasma in the plasma plume. Magnetic filtering functions in a corresponding way by deviating the plasma jet, so that the particles are separated from the plasma.

According to the invention, the term ‘surface’ can thus refer either to a surface or to 3D material. Here the concept ‘surface’ is not subjected to any geometric or three-dimensional restrictions.

The coating of a substrate according to the invention enables the formation of uniform, pinhole-free surfaces along the whole surface of the object.

In accordance with the invention, the substrate can be made of for instance metal, metal compound, glass, stone, ceramics, synthetic polymer, semisynthetic polymer, natural polymer, paper, cardboard, composite material, inorganic or organic monomeric or oligomeric material, or a combination of one or more of the above mentioned substrates.

Likewise, the target can be made of for instance metal, metal compound, glass, stone, ceramics, synthetic polymer, semisynthetic polymer, natural polymer, composite material, inorganic or organic monomeric or oligomeric material, or a combination of one or more of the above mentioned targets.

Here a semisynthetic compound means for instance manipulated natural polymers or composites containing these.

Consequently, the invention is not restricted to any given substrate or target.

In accordance with the invention, metal can be coated for instance with another metal, metal compound, glass, stone, ceramics, synthetic polymer, semisynthetic polymer, natural polymer, composite material, inorganic or organic monomeric or oligomeric material, or with a combination of one or more of the above mentioned substrates.

A metal compound can be coated for instance with metal, another metal compound, glass, stone, ceramics, synthetic polymer, semisynthetic polymer, natural polymer, composite material, inorganic or organic monomeric or oligomeric material, or with one or more combinations of said substrate.

Glass can be coated for instance with metal, metal compound, another glass, stone, ceramics, synthetic polymer, semisynthetic polymer, natural polymer, composite material, inorganic or organic monomeric or oligomeric material, or with one or more combinations of said substrate.

Stone can be coated for instance with metal, metal compound, glass, another stone, ceramics, synthetic polymer, semisynthetic polymer, natural polymer, composite material, inorganic or organic monomeric or oligomeric material, or with one or more combinations of said substrate.

Ceramics can be coated for instance with metal, metal compound, glass, stone, other ceramics, synthetic polymer, semisynthetic polymer, natural polymer, composite material, inorganic or organic monomeric or oligomeric material, or with one or more combinations of said substrate.

Paper can be coated for instance with metal, metal compound, glass, stone, ceramics, synthetic polymer, semisynthetic polymer, natural polymer, composite material, inorganic or organic monomeric or oligomeric material, or with one or more combinations of said substrate.

Synthetic polymer can be coated for instance with metal, metal compound, glass, stone, ceramics, another synthetic polymer, semisynthetic polymer, composite material, natural polymer, inorganic or organic monomeric or oligomeric material, or with one or more combinations of said substrate.

Further, semisynthetic polymer can, according to the invention, be coated for instance with metal, metal compound, glass, stone, ceramics, synthetic polymer, another semisynthetic polymer, natural polymer, composite material, inorganic or organic monomeric or oligomeric material, or with one or more combinations of said substrate.

Further, natural polymer can according to the invention be coated for instance with metal, metal compound, glass, stone, ceramics, synthetic polymer, semisynthetic polymer, another natural polymer, composite material, inorganic or organic monomeric or oligomeric material, or with one or more combinations of said substrate.

Further, composite material can according to the invention be coated for instance with metal, metal compound, glass, stone, ceramics, synthetic polymer, semisynthetic polymer, natural polymer, another composite material, inorganic or organic monomeric or oligomeric material, or with one or more combinations of said substrate.

One definition of composite is found, among others, in the Polymer Science Dictionary (Alger, M. S. M, Elsevier Applied Science, 1990, p. 81), which defines composite material as follows: “Solid material formed of the material combination of two or more simple (or monolithic) materials, and where the individual components keep their separate identities. Composite material has different features than its individual component materials; the use of the concept ‘composite’ often refers to improved physical features, because technologically the main object is to realize materials that have superior features when compared with the component materials of the composite. Composite material also is a heterogeneous structure formed of two or more phases obtained from the composite components. The phases can be continuous, or one or several of the phases can be dispersed within a continuous matrix”.

According to the invention, it is also possible to manufacture, apart from completely new compounds, also such composites where two or more materials build a composite on the molecular level. In an embodiment of the invention, there are made surfaces or 3D structures for example from polysiloxane and diamond, and in another embodiment of the invention, there are made surfaces or 3D structures for example from polysiloxane and carbon nitride (carbonitride). According to the invention, the contents of two or more material components of the composite can be freely chosen.

Further, inorganic monomeric or oligomeric material can according to the invention be coated with metal, metal compound, glass, stone, ceramics, synthetic polymer, semisynthetic polymer, natural polymer, composite material, another inorganic or organic mono- or oligomeric material, or with one or more combinations of said substrate.

Yet further, organic monomeric or oligomeric material can according to the invention be coated with metal, metal compound, glass, stone, ceramics, synthetic polymer, semisynthetic polymer, natural polymer, composite material, inorganic or other organic mono- or oligomeric material, or with one or more combinations of said substrate.

According to the invention, the combinations of all preceding substrates can also be coated with one or more combinations of said substrate.

According to a preferred embodiment of the invention, the surface to be coated is formed so that the surface contains less than one pinhole per 1 mm², advantageously less than one pinhole per cm² and preferably not any pinholes at all in the whole coated area. Here the term ‘pinhole’ means either a hole penetrating the whole surface, or then an essentially penetrating pinhole. The invention also relates to a product coated by the method according to the invention, where the surface contains less than one pinhole per 1 mm², advantageously less than one pinhole per cm² and preferably not any pinholes at all in the whole coated area.

In another preferred embodiment of the invention, the surface to be coated is realized so that the first 50% of the surface is formed so that on the created surface, there are not deposited particles with a diameter larger than 1000 nm, advantageously so that the size of said particles does not surpass 100 nm and preferably so that the size of said particles does not surpass 30 nm. The invention also relates to a product coated according to the method according to the invention, where the first 50% of the created surface does not contain particles with a diameter larger than 1000 nm; advantageously it does not contain particles with a size that surpasses 100 nm, and preferably it does not contain particles with a size that surpasses 30 nm. In case the surface structure contains described particles, they essentially weaken the surface quality. The particles form corrosion gaps that also shorten the lifetime of the created surface.

In an embodiment of the invention, the ablated material can be used in 3D printing. 3D printing according to the prior art known at the priority date of the present application (e.g. brands JP-System 5 of Scroff Development Inc., Ballistic Particle Manufacturing of BPM Technology Inc., the Model Maker of Solidscape Inc., Multi Jet Modelling of 3D Systems Inc., and Z402 System of Z Corporation) utilizes materials the mechanical strength of which is relatively poor. Since an apparatus according to an embodiment of the invention achieves a high efficiency, a fast layer growth rate in a relatively cost effective manner, it is possible, e.g. by ablating carbon either in graphite form or as diamond, to make the ablated material to be conducted, e.g. according to the principle of the ink jet printer, into layers which, slice by slice, correspond to the object to be printed. Thus, when using carbon, for instance, it is possible to fabricate structures hard enough. The embodiment of the invention is not, however, limited to diamond, but other materials, too, can be used in accordance with the choice of the ablated material. Thus an apparatus according to an embodiment of the invention can be used to produce either hollow or solid objects from almost any applicable material, such as diamond or carbonitride, for instance.

Thus it would be possible, for example, to print out, slice by slice, the famous statue of David in diamond layers and then, using ablation, to smooth out potential edges between slices. The statue could be given a certain hue, even separately for each layer, if desired, by suitably doping the diamond. It would also be possible to directly print out almost any 3D piece, such as a spare part, tool, display element, shell structure or part thereof for a PDA or mobile communications device, for example.

In the coating method according to the invention, laser ablation is carried out by a pulse laser. In a particularly advantageous embodiment of the invention, the laser apparatus used for ablation is a cold work laser, such as a picosecond laser. In another preferred embodiment of the invention, the laser apparatus is a femtosecond laser, and yet in another preferred embodiment it is an attosecond laser.

In the method according to the invention, the power of the cold work laser is advantageously at least 10 W, more advantageously at least 20 W and preferably at least 50 W. Here a top limit is not set for the power of the laser apparatus.

In the method according to the invention, a high-quality surface that is sufficiently wear-resistant for the target application and has sufficient optical features (has desired color or is transparent) can be achieved so that the substrate is coated, by means of laser ablation, in a coarse vacuum or even in a gas atmosphere with normal air pressure.

The coating can be carried out at room temperature, or near room temperature, for instance so that the substrate temperature is roughly 60° C., or so that the substrate temperature is raised remarkably (>100° C.).

This is particularly advantageous when coating large objects (wide substrate surface), such as stone, metal, composite and various polymer plates for the needs of the building industry. With current coating methods, the taking of these kind of objects into a sufficiently high vacuum does, apart from being extremely expensive, also dramatically lengthen the throughput times of the coating process. In several target applications, for instance when coating porous materials (stone etc.), a high vacuum is impossible to reach. In case also heating should be combined in the process, with many stone species there may occur crystal water, which naturally breaks up the structure of said stone material and weakens or prevents its use in the target application.

In case the coating can be performed in normal atmosphere or in a low vacuum near to the normal atmosphere, it is thus significant both in the qualitative and particularly in the economical respect. In some target applications, it enables the making of products that were earlier impossible to manufacture.

For example many stone products can according to the invention be coated with aluminum oxide for achieving a wear-resistant surface. This kind of surface prevents the accumulation of gases, but also of also moisture and hence the accumulation of for instance stone-breaking fungoid materials or ice inside the stone material or on the surface thereof. According to the invention, stone material can be coated either directly with aluminum oxide, or for example first with aluminum, whereafter the created aluminum surface can be oxidized by several different methods, such as RTA+ light, thermal oxidation (500° C.) or thermal oxidation in boiling water. In case certain elements, such as zirconium, is added in the aluminum, the oxidizing metal surface is still better enlarged than with mere aluminum, and forms a tight oxide surface that is effectively spread to all holes of the stone. At the same time, the surface becomes transparent. According to the invention, the stone material can also be colored to the desired shade by adding pigments or color elements onto the surface prior to the final surface formation by oxidation. This kind of colored surface of a stone product can be produced by laser ablation according to the invention. In accordance with the invention, the aluminum oxide surface can be replaced by any other hard surface, such as diamond surface, carbon nitride surface, another stone surface or some other oxide surface. In an embodiment of the invention, the topmost surface of a stone product becomes a self-cleaning surface.

This kind of self-cleaning surface can be made for instance of titanium or zinc oxide. According to the invention, the substrate can be coated either directly with the desired oxide, or by vaporizing the desired metal in an oxygen-containing gaseous atmosphere. Advantageously the thickness of a self-cleaning surface according to the invention is 10 nm-150 nm, more advantageously 15 nm-100 nm and preferably 20 nm-50 nm.

In case a surface with UV protection is wished on the substrate surface, the previous photocatalytic surface can be further coated with an aluminum layer.

In another embodiment of the invention, the laser ablation is carried out in a vacuum with 10⁻¹-10⁻¹² atmospheres.

In case the coating is performed in a vacuum, the coating according to the invention, or the manufacturing of a 3D object, is carried out in the pressure of advantageously 10⁻³-10⁻⁹ atmospheres, and preferably in the pressure of 10⁻⁴-10⁻⁸ atmospheres.

In case a higher vacuum is used, this is according to an embodiment of the invention useful particularly when forming surfaces of monocrystalline material, such as monocrystalline diamond, aluminum oxide or silicon. Monocrystalline diamond or silicon materials produced according to the invention can be used for example as semiconductors, with diamond also as jewelry, parts of laser equipment (light beams in a diode pump, lens arrangements, fibers), as extremely durable surfaces in applications where such surfaces are needed, etc.

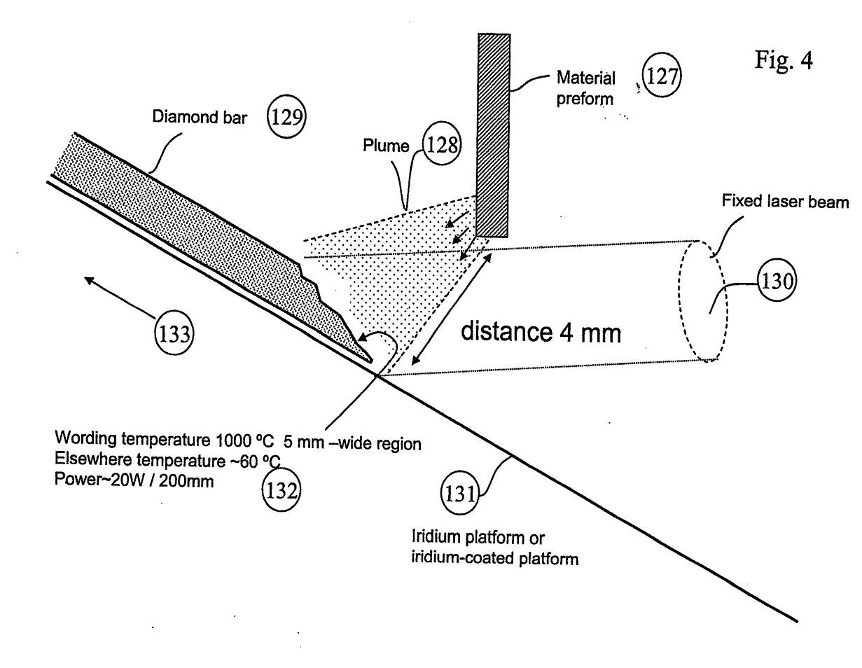

According to the invention, a semiconductor diamond can be accreted for instance on an iridium substrate (FIG. 4), and semiconductor silicon can be accreted for instance directly on top of plastic or paper. In case the silicon layer is sufficiently thin, for instance 5-15 μm, this kind of semiconductor can be bent, and it can be further used for manufacturing for example bendable electronics. Both diamond-based and silicon-based semiconductor materials can be cut into desired shapes by laser ablation, advantageously by means of picosecond laser and preferably by a picosecond laser provided with a turbine scanner.

In another embodiment according to the invention, on top of the substrate there is deposited one or several diamond surfaces. In this kind of diamond surface, the quantity of sp3 bonds is advantageously extremely high, and—opposite to the case with for example prior art DLC surfaces (Diamond Like Carbon)—the obtained surface is extremely hard and scratch-free with all surface thicknesses according to the invention. The diamond surface is preferably transparent. In addition, it endures high temperatures, as opposed to the prior art poor-quality DLC that in the thickness of 1 micrometer becomes black and only endures temperatures of 200° C. The diamond surface produced according to the method of the invention is preferably fabricated of a carbon source that does not contain hydrogen. Advantageously the carbon source is sintered carbon, and preferably it is pyrolytic carbon, vitreous carbon.

According to the invention, pyrolytic carbon is a particularly advantageous target when manufacturing monocrystalline diamond or particle-free surfaces for instance for MEMS applications.

In case a poorer quality DLC surface should be made, even the manufacturing of this kind of surface according to the invention is fast and economical.

In case the diamond surface should be colored, the created diamond surface can be shaded with color by vaporizing, in addition to carbon, also an element or compound giving the desired color.

A diamond surface produced according to the invention prevents the lower surfaces, apart from mechanical wear, also from being subjected to chemical reactions. A diamond surface prevents for instance metals from oxidation, and thus it prevents the destruction of their decorative or other function. In addition, a diamond surface protects lower surfaces from acidic and alkaline agents.

In a preferred embodiment of the method according to the invention, the target is ablated by a laser beam, so that the material is vaporized essentially continuously at a spot of the target that was previously significantly non-ablated.

This can be achieved by moving the target, so that a fresh surface is always ablated. In currently known methods, the material preform is normally in the form of a thick bar or plate. Consequently, there must be used a focusing zoom lens, or the material preform must be transferred towards the laser beam along with the wearing of the material preform. Already a mere attempt at realizing this is extremely difficult and expensive, if normally at all possible to be carried out sufficiently reliably, and yet the fluctuation of the quality is high, which means that an accurate control is nearly impossible, the manufacturing of a thick preform is expensive etc.

Because the technique for controlling the laser beam is limited, among others owing to the prior art scanners, this is not successful without interference, particularly if the pulse frequency of the laser equipment is raised. If one attempts to increase the pulse frequency up to 4 MHZ or further, the scanners according to the prior art will cause a significant part of the pulses of the laser beam being directed uncontrollably onto the wall structures of the laser apparatus, and also into the ablated material in the form of plasma, having the net effect that the quality of the surface to be produced will suffer as will also the production rate and, furthermore, the radiation flux hitting the target will not be uniform enough, which may affect the structure of the generated plasma, which thus may, upon hitting the surface to be coated, produce a surface of uneven quality. In case the laser beam hits completely or partly a surface that was already ablated before, the distance between the target and the substrate is changed at said pulses. When the pulses directed to the target hit already ablated spots in the target, at various pulses there are detached different quantities of material, so that particles with sizes of several microns are ablated from the target. Such particles remarkably deteriorate the quality of the created surface when hitting the substrate, and hence they also deteriorate product features.

In an embodiment of the invention, the target material a prior art target material set in a rotary motion, as is described in the US patent publication U.S. Pat. No. 6,372,103. In another embodiment according to the invention, the target material is a plate-like target plate that is also commercially available.

In a preferred embodiment of the invention, the target material is fed as film/tape feed.

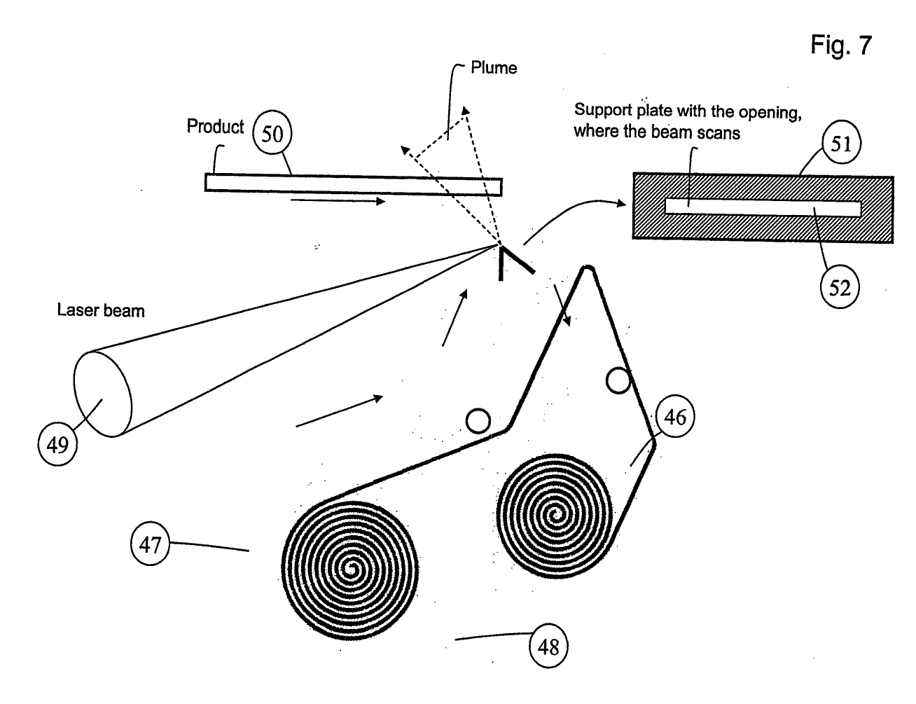

In one such preferred embodiment, the film/folio is now for instance in reel form, as is illustrated in FIG. 7. When the tape is first vaporized in the lengthwise direction from beginning to end at the width of one laser plume, the tape/folio is shifted for instance sideways to the extent that there can be created a completely new groove. This can be continued, until the folio/film is completely consumed in the transversal direction. The most essential significance of this system naturally is that the vaporizing result always is constant and represents top level, because the source material remains continuously constant.

Another embodiment of the invention, based on the fact that the folio/tape (46) illustrated in FIG. 7 is a) thinner, b) as thick as or c) thicker than the focus depth of the laser beam. As for case c), that part of the material that is larger (thicker) than the focus depth of the laser beam, is collected and stored on a separate reel (48). The thickness of the tape/folio can be for instance 5 μm-5 mm, advantageously 20 μm-1 mm and preferably 50 μm-200 μm.

In a particularly preferred embodiment of the invention, the distance between the target and the substrate is maintained essentially constant throughout the whole ablation process.

In yet another coating method according to a preferred embodiment of the invention, a mechanism for adjusting the laser beam focus is not needed, which means that in the folio/film vaporizing method according to an embodiment of the invention, the focus adjusting step is not needed as such. The mechanism as such not needed when the virginal surface of the film feed serves as a target, because said folio/film remains in focus as permanently adjusted. Only that material part of the film that corresponds to the focus depth of the laser beam is utilized. Thus there is achieved a coating result with a uniform quality, and a separate focusing unit for the duration of the coating process is not needed. Target materials are valuable, and therefore advantageously only the new, virginal surface part of the target surface is used; hence, it is also industrially preferable to use as thin targets as possible. Tape-shaped target materials are naturally remarkably cheaper than current target materials and better available owing to their easier and economical production methods.

In another preferred embodiment of the invention, the coating process applies lamella feed. Now for the coating of each new piece, there is fed a new lamella-like target. This feeding method of the material is well suited for instance with ceramic aluminum oxide plates that are currently used for the routine of making small, thin and smooth plates. The production of large targets is normally troublesome and expensive.

In prior art arrangements, the scanning width presents a problem. Linear scanning has been used in mirror film scanners, in which case it is theoretically possible to assume that a nominal, roughly 70 mm scan line width can be achieved, but in practice the scanning width can problematically remain even at around 30 mm, in which case the fringes of the scanning range can remain non-homogeneous in quality, and/or different than the central areas. Scanning widths this small make the use of current laser equipment for the coating applications of large, wide objects also in this respect industrially unprofitable or technically impossible to realize.

In a preferred embodiment of the invention, the laser beam is directed to the target via a turbine scanner.

A turbine scanner alleviates the power transmission problems connected to earlier planar mirror scanners, so that the target material can be vaporized at a sufficiently high pulse power, thus producing plasma with a high and homogeneous quality, and hence surfaces and 3D structure with a high quality. The turbine scanner also facilitates larger scanning widths than before, and consequently the coating of larger surface areas with one and the same laser apparatus. Thus a good working speed is achieved, and the quality of the created surface becomes homogeneous. In a preferred embodiment according to the invention, the scanning width directed to the target can be 10 mm-700 mm, advantageously 100 mm-400 mm and preferably 150 mm-300 mm.

In small-size applications, it must naturally be smaller.

Consequently, the invention must not be restricted to one laser source only. According to an embodiment of the invention, the substrate is kept immobile in the plasma plume vaporized of one or more targets. According to a preferred embodiment of the invention, the substrate is moved in a plasma plume vaporized of one or more targets by laser ablation. In case the coating is carried out in a vacuum or in reactive gas, the coating is advantageously made in a separate vacuum chamber.

In accordance with the invention, there can be produced surfaces and/or 3D materials having various functions. Such surfaces include for example very hard and scratch-free surfaces and 3D materials in various glass and plastic products (lenses, monitor shields, windows in vehicles and buildings, glassware in laboratories and households), in which case particularly advantageous optical coatings are MgF₂, SiO₂, TiO₂, Al₂O₃, and particularly advantageous hard coatings are various metal oxides, carbides and nitrides, as well as obviously diamond coatings; various metal products and their surfaces, such as shell structures for telecommunication devices, roofing sheets, decoration and construction panels, linings, and window frames; kitchen sinks, faucets, ovens, coins, jewels, tools and parts thereof; engines of automobiles and other vehicles and parts thereof, metal claddings and painted metal surfaces in automobiles and other vehicles, objects with metal surfaces used in ships, boats and airplanes, aircraft turbines, and combustion engines; bearings; forks, knives, and spoons; scissors, hunting knives, rotary blades, saws, and all types of cutters with metal surfaces, screws, and nuts; metallic processing means used in chemical industry processes, such as reactors, pumps, distilling columns, containers, and frame structures having metal surfaces; piping for gas and chemicals; various valves and control units; parts and drill bits of oil drilling equipment; pipes for transporting water; weapons and their parts, bullets, and cartridges; metallic nozzles susceptible to wear, such as papermaking machine parts susceptible to wear, e.g. parts of the coating paste spreading equipment; snow pushers, shovels, and metallic structures of playground equipment; roadside railing structures, traffic signs and posts; metal cans and vessels; surgical equipment, artificial joints, implants and instruments; cameras and video cameras and metallic parts in electronic devices susceptible to oxidation and wear, and spacecrafts and their cladding solutions resistant to friction and high temperatures.

Yet other products manufactured in accordance with the invention may include surfaces and 3D materials resistant to corrosive chemical compounds, semiconductor materials, LED materials, pigment materials and surfaces made thereof which change color according to the viewing angle, the already mentioned parts of laser equipment and diode pumps, such as beam expanders and the light bar in the diode pump, jewel materials, surfaces of medical products and medical products in 3D shapes, self-cleaning surfaces, various products for the construction industry such as pollution- and/or moisture-resistant and, if necessary, self-cleaning stone and ceramic materials (coated stone products and products onto which a stone surface has been deposited), dyed stone products, e.g. marble dyed green in accordance with an embodiment of the invention or self-cleaning sandstone.

Further products fabricated according to the invention may include anti-reflective (AR) surfaces e.g. in various lens and monitor shielding solutions, coatings protective against UV radiation, and UV-active surfaces used in the cleansing of solutions or air.

Thus, the thicknesses of the created surfaces can be adjusted. For instance the thickness of a diamond surface of carbon nitride deposited according to the invention can be for example 1 nm-3000 nm. In addition, the diamond surface can be made extremely uniform. The uniformity of the diamond surface can be of the order ±30 nm; preferably it is ±10 nm and in some extremely demanding, low-friction targets its uniformity can be adjusted on the level ±2 nm. Hence, a diamond surface according to the invention thus prevents the lower surfaces, apart from being mechanically worn, also from being subjected to chemical reactions. A diamond surface prevents for instance the oxidation of metals and thus the destruction of their decorative or other function. In addition, a diamond surface protects the lower surfaces against acidic and alkaline agents. In certain applications, decorative metal surfaces are desired. Among particularly decorative metals or metal compounds to be utilized as targets according to the invention are for instance gold, silver, chromium, platinum, titanium, tantalum, copper, zinc, aluminum, iron, steel, zinc black, ruthenium black, ruthenium, cobalt, vanadium, titanium nitride, titanium aluminum nitride, titanium carbonitride, zirconium nitride, chromium nitride, titanium silicon carbide and chromium carbide. Naturally other features can also be achieved with said compounds, for instance wear-resistant surfaces, or surfaces protecting from oxidation or other chemical reactions.

Among metal compounds, let us here mention metal oxides, nitrides, halides and carbides, but the number of possible metal compounds must not be restricted to these only.

Various oxide surfaces to be produced according to the invention are among others: aluminum oxide, titanium oxide, chromium oxide, zirconium oxide, tin oxide, tantalum oxide etc. as well as combinations of these as composites together with each other or for example metals, diamond, carbides or nitrides. As was already maintained, the above enlisted materials can according to the invention be also manufactured of metals by using a reactive gas environment.

In addition, the present invention relates to an object coated by the laser ablation method on one or several surfaces, which object, i.e. substrate, is coated by ablating the target so that the uniformity formed in the coated object is ±100 nm, when measured in the area of one square micrometer with an atomic force microscope (AFM).

In a preferred embodiment of the invention, the uniformity of a surface deposited on a coated object is ±25 nm, and in an even more preferred embodiment of the invention, the uniformity of a surface deposited on a coated object is ±2 nm.

In a preferred embodiment of the invention, the coated surface of an object does not contain particles with a diameter larger than 1 μm. Even more advantageously, the coated surface of an object of the invention does not contain particles with a diameter larger than 100 nm. In yet more advantageously, the coated surface of an object of the invention does not contain particles with a diameter larger than 25 nm.

The object according to the invention can be for instance made of metal, metal compound, glass, stone, ceramics, synthetic polymer, semisynthetic polymer, natural polymer, paper, composite material, inorganic or organic mono- or oligomeric material. An object according to the invention can be coated for instance with metal, metal compound, glass, stone, ceramics, synthetic polymer, semisynthetic polymer, natural polymer, composite material, inorganic or organic mono- or oligomeric material.

Some objects according to the invention are coated by laser ablation, so that the laser ablation is carried out by pulse laser. In a particularly preferred embodiment of the invention, the employed laser apparatus is a cold working laser, such as a picosecond laser. It can also be a femtosecond or an attosecond pulse laser.

In case a picosecond pulse laser is used for coating an object according to the invention, the power of said laser apparatus in one embodiment is at least 10 W. In a more preferred embodiment of the invention, the power of the employed laser apparatus is at least 20 W, and in a yet more advantageous embodiment, the power of the employed laser apparatus has been at least 50 W.

In an embodiment of the invention, the object is coated so that the laser ablation is carried out in a vacuum with 10⁻¹-10⁻¹² atmospheres. In another embodiment of the invention, the object is coated so that laser ablation is carried out in normal air pressure.

In a particularly advantageous embodiment of the invention, the object is coated so that the target is ablated by a laser beam so that the material is vaporized essentially continuously at a spot of the target that was earlier significantly non-ablated. One method according to the invention for coating an object in the way described above is that the target is fed as lamella feed, another method is that the target is fed as film/tape feed. In case the target is fed as film/tape feed, the thickness of the target is advantageously 5 μm-5 mm, more advantageously 20 μm-1 mm and preferably 50 μm-200 μm.

The can also have been a conventional, bulky prior art target, either a mobile solution or one kept in a static position.

Some objects according to the invention are advantageously manufactured so that the laser beam employed in the ablation is directed through a target turbine scanner. In that case the scanning width directed to the target can have been for example 10 mm-800 mm, advantageously 100 mm-400 mm and preferably 150 mm-300 mm.

In small-size applications, it must naturally be smaller.

An object according to the invention is in an embodiment also manufactured so that the substrate is moved by laser ablation in a plasma plume vaporized of one or more targets. In a preferred embodiment of the invention, the object is made so that the distance between the target and the substrate is kept essentially constant during the whole ablation process.

The surface of the object according to the invention can also have been deposited of material ablated from several different targets simultaneously. In a further embodiment of an object of the invention, the surface of the object is formed so that in the plasma plume generated of the ablated material, there is brought reactive material that reacts with the ablated material contained in the plasma plume, and the created compound or compounds constitute the surface to be deposited on the substrate.

### EXAMPLES

The method and product according to the invention are described below, without, however, exclusively restricting the invention to the given examples. For producing the surfaces, there were used both the X-lase 10 W picosecond laser made by Corelase Oy, and the X-lase 20 W-80 W picosecond laser, (USPLD), by Corelase. Here pulse energy refers to the pulse energy received on an area of one square centimeter, which is focused on a desired surface area by means of optics. The employed wavelength was 1064 nm. The temperature of the coated material varied from room temperature to as high as 200° C. In the various products, the target material temperature was adjusted between room temperature and 700° C. Both oxides, metals and various carbon-based target materials were used in the coating processes. When the coatings were made in a oxygen phase, the oxygen pressure varied from 10⁻⁴ to 10⁻¹ mbar. In the low-power laser, the employed scanner was an ordinary mirror scanner, i.e. a galvanic scanner. In subsequent coatings, there was used a scanner that turns around its axis, i.e. a turbine scanner. The turbine scanner enabled an adjustable scanning rate, and the scanning rate of the beam directed to the target material could be adjusted within the range 1 m/s-350 m/s. A successful use of a galvanic scanner requires lower pulse frequencies, typically lower than 1 MHz. On the other hand, with a turbine scanner, high-quality coatings could be produced even with high repetition frequencies, such as 1 MHz-30 MHz. The produced coatings were examined with AFM, ESEM, FTIR and Rama, as well as with a confocal microscope. Moreover, the optical features (transmission) as well as certain electronic features, such as resistivity, were examined. The employed spot size varied within the range 20-80 μm. All examined surfaces were pinhole-free. Coarseness, i.e. surface uniformity, was measured in the area of 1 μm² with AFM equipment.

### Example 1

In this example, marble was coated by a diamond coating (of sintered carbon). The performance parameters of the laser apparatus were as follows:

repetition frequency 4 MHz
pulse energy 5 μJ
pulse length 20 ps
distance between target and substrate 4 mm.
vacuum level: 10⁻⁶ atmospheres

The created diamond surface was examined by AFM equipment (Atomic Force Microscope). The diamond surface thickness was roughly 500 nm, and the surface uniformity ±10 nm. Microparticles were not observed on the surface.

### Example 2

In this example, an aluminum film was coated by diamond coating (of sintered carbon). The performance parameters of the laser apparatus were as follows:

repetition frequency 4 MHz
pulse energy 5 μJ
pulse length 20 ps
distance between target and substrate 4 mm.
vacuum level: 10⁻⁵ atmospheres

The aluminum film was colored in a sky-blue shade. The created diamond surface was examined by an AFM equipment (Atomic Force Microscope). The diamond surface thickness was roughly 200 nm, and the surface uniformity ±8 nm. Microparticles were not observed on the surface.

### Example 3

In this example, a silicon disc, a silicon dioxide object, a polycarbonate plate and a mylar film were coated by diamond coating (of pyrolytic carbon). The performance parameters of the laser apparatus were as follows:

repetition frequency 4 MHz
pulse energy 2.5 μJ
pulse length 20 ps
distance between target and substrate 8 mm.
vacuum level: 10⁻⁵ atmospheres

The created diamond surface was examined by AFM equipment (Atomic Force Microscope). The diamond surface thickness was roughly 150 nm, and the surface uniformity ±20 nm. Neither micro nor nano particles were observed on the surface.

### Example 4

In this example, a silicon dioxide object was coated with diamond coating. The performance parameters of the laser apparatus were as follows:

repetition frequency 2 MHz
pulse energy 10 μJ
pulse length 15 ps
distance between target and substrate 2 mm.
vacuum level: 10⁻³ atmospheres

The created diamond surface was examined by AFM equipment (Atomic Force Microscope). The diamond surface thickness was roughly 50 nm, and the surface uniformity ±4 nm. Microparticles were not observed on the created surface. The surface coarseness was excellent, and the nano particle size was at most 20 nm.

### Example 5

In this example, a copper plate object was coated with copper oxide. Performance parameters of the laser apparatus were as follows:

repetition frequency 4 MHz
pulse energy 5 μJ
pulse length 17 ps
distance between target and substrate 10 mm.
Vacuum level: 10⁻¹ atmospheres

As a result of the coating process, there was created a copper oxide surface with a uniform quality. The thickness of the created surface was roughly 5 μm.

### Example 6

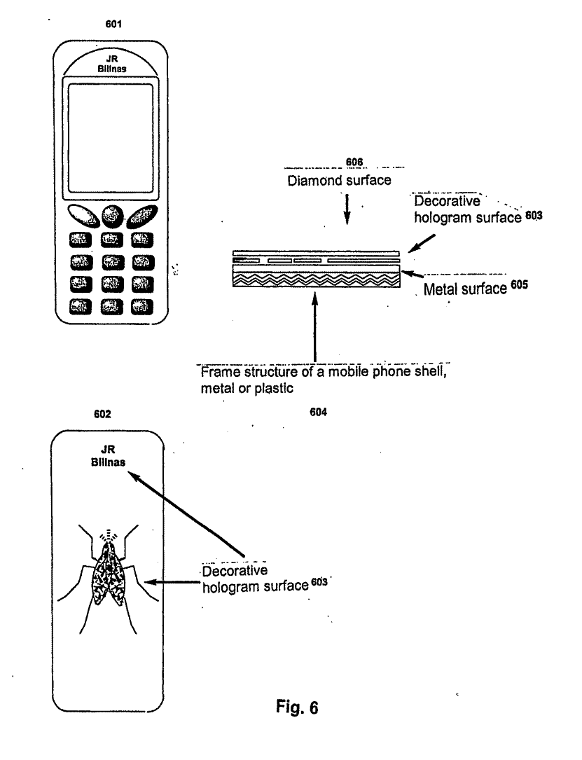

Example 6 deals with a decorative snow pusher that is diamond coated by laser ablation (FIG. 6). Owing to the diamond surface, the snow pusher is extremely wear-resistant and scratch-free. In addition, the hydrophobic nature of the diamond surface, and particularly the nano grade uniformity in the surface, reduce friction and make snow pushing less energy-consuming and thus easier.

The frame material of the snow pusher can be for instance plastic or metal. In the snow pusher of the example, on top of the aluminum frame material, there is electrolytically made a chromium one micrometer metal layer. As an alternative, this can according to the invention be made by laser ablation. The metal coating to be made on the plastic surface is most easily realized exactly by means of laser ablation (cold ablation). The employed metal, metal alloy or metal compound, as well as the surface thickness, can be freely chosen, and consequently the snow pusher can thus be easily made personal-looking. The forming of the metal surface, particularly by laser ablation, enables an advantageous creation of extremely thin and yet desired basic color rendered by the metal surface. The diamond coating provided on all surfaces now protects the surfaces of these metals against oxidation or mechanical wear. Individual features can be added by hologram surfaces, in which case figures or text according to the customer's wishes can be realized on the surface. Apart from mechanical engraving, a hologram surface can also be realized extremely efficiently by laser engraving, in which case the engraving can be made on the desired surface accurately, rapidly and economically. The high quality of the hologram surface improves the uniform quality of the metal surface located underneath it and produced by laser ablation. Here the uniformity of the surface means surface coarseness, and it was measured in all samples by using an atomic force microscope in an area of 1 μm².

In reality, the surfaces illustrated in the image are physically attached, but for the sake of illustration, they are shown as separate elements.

### Example 7

In this example, marble was coated with an aluminum oxide coating. The performance parameters of the laser apparatus were as follows, and the surface was formed by directly ablating aluminum oxide:

repetition frequency 4 MHz
pulse energy 4 μJ
pulse length 10-20 ps
distance between target and substrate 3 mm.
vacuum level: 10⁻⁶ atmospheres

The created aluminum oxide surface was examined by AFM equipment (Atomic Force Microscope). The aluminum oxide thickness was roughly 500 nm, and the surface uniformity ±5 nm. Microparticles were not observed on the surface.

### Example 8

In this example, marble was coated with aluminum oxide coating. The performance parameters of the laser apparatus were as follows, and the surface was formed by directly ablating aluminum oxide:

repetition frequency 4 MHz
pulse energy 4 μJ
pulse length 10 ps
distance between target and substrate 3 mm.
vacuum level: 0

The created aluminum oxide surface was examined by AFM equipment (Atomic Force Microscope). The aluminum oxide surface thickness was roughly 5 μm, and the surface uniformity ±10 nm. Nano particles were observed on the surface.

### Example 9

In this example, a pre-varnished plastic spectacle lens was coated with aluminum oxide coating. The performance parameters of the laser apparatus were as follows, and the surface was formed by directly ablating aluminum oxide:

repetition frequency 4 MHz
pulse energy 4 μJ
pulse length 20 ps
distance between target and substrate 3 mm.
vacuum level: 10⁻⁶ atmospheres

The created aluminum oxide surface was examined by AFM equipment (Atomic Force Microscope). The aluminum oxide surface thickness was roughly 300 nm, and the surface uniformity ±2 nm. Micro or nano particles were not observed on the surface.

### Example 10

In this example, a granite object was coated with aluminum oxide coating. The performance parameters of the laser apparatus were as follows, and the surface was formed by directly ablating aluminum oxide:

repetition frequency 4 MHz
pulse energy 4 μJ
pulse length 10 ps
distance between target and substrate 9 mm.
vacuum level: 10⁻³ atmospheres

The created aluminum oxide surface was examined by AFM equipment (Atomic Force Microscope). The sapphire surface thickness was roughly 1 μm, and the surface uniformity ±9 nm. Remarkable quantities of nano or micro particles were not observed on the surface.

### Example 11

In this example, a plastic mobile phone shell was coated with aluminum, and thereafter with aluminum oxide coating. The performance parameters of the laser apparatus were as follows, and the surface was formed by directly ablating aluminum oxide:

repetition frequency 4 MHz
pulse energy 4 μJ
pulse length 10 ps
distance between target and substrate 3 mm.
vacuum level: 10⁻⁶ atmospheres

The created aluminum oxide surface was examined by AFM equipment (Atomic Force Microscope). The surface thickness was roughly 300 nm, and the surface uniformity ±5 nm. Neither micro nor nano particles were observed on the surface. The surface of the aluminum layer was not measured.

### Example 12

In this example, a steel object was coated with titanium oxide coating. The performance parameters of the laser apparatus were as follows, and the surface was formed by ablating titanium in an oxygen-containing helium sphere:

repetition frequency 20 MHz
pulse energy 4 μJ
pulse length 10 ps
distance between target and substrate 1 mm.
vacuum level: 10⁻² atmospheres

The created titanium oxide surface was examined by AFM equipment (Atomic Force Microscope). The titanium oxide surface thickness was roughly 50 nm, and the surface uniformity ±3 mm.

### Example 13

In this example, a bone screw made of stainless steel was coated with diamond coating. The performance parameters of the laser apparatus were as follows, and the surface was created by directly ablating titanium dioxide: repetition frequency 20 MHz, pulse energy 4 μJ, pulse length 10 ps, distance between target and substrate 1 mm and vacuum level: 10⁻⁵ atmospheres. The surface of the created titanium dioxide was examined by AFM equipment (Atomic Force Microscope). The thickness of the diamond surface was roughly 100 nm, and the surface uniformity ±3 nm (coarseness).

### Example 14

In this example, a bone screw made of stainless steel was coated with diamond coating. The performance parameters of the laser apparatus were as follows, and the surface was formed by sintered carbon: repetition frequency 4 MHz, pulse energy 2.5 μJ, pulse length 20 ps, distance between target and substrate 8 mm, vacuum level: 10⁻⁷ atmospheres. The created diamond surface was examined by AFM equipment (Atomic Force Microscope). The diamond surface thickness was roughly 100 nm, and surface uniformity ±3 nm.

### Example 15

A piece of copy paper sheet (80 g/mm², white), size 100 mm×100 mm, was coated by ablating titanium dioxide at the pulse repetition frequency 4 MHz. The pulse energy was 5 μJ, the pulse length 20 ps and the distance between the target and the target to be coated was 60 mm. The vacuum level was 10⁻⁵ atmospheres during the coating process. The coating resulted in a uniform and transparent coating. The coating thickness was roughly 110 nm.

### Example 16

A piece of copy paper (80 g/mm², white), size 100 mm×100 mm, was coated by ablating with an oxide-form indium tin oxide (90 p. % In₂O₃; 10 p. % SnO₂) at the pulse frequency 3 MHz and the pulse length 20 ps. The distance between the target and the target to be coated was 40 mm, and the vacuum level during the coating process was 10⁻⁵ atmospheres. The coating resulted in a uniform, transparent coating with a measured thickness of 570 nm.

### Example 17

A glass plate, measures 300 mm×300 mm, was coated by ablating vanadine from metal in an active oxygen phase. The oxygen pressure varied from 10⁻⁴ to 10⁻¹ mbar during the coating process. The pulse repetition frequency was 25 MHz, the pulse energy 5 μJ, and the distance between target and substrate 30 mm. The glass material was preheated up to roughly 120° C. prior to the coating. Before coating, the vacuum level was maintained at 10⁻⁵ mbar. The coating produced a transparent vanadine oxide coating, and the measured thickness was 10 nm. The measured surface coarseness was 0.14 nm in the area of 1 μm². The surface coarseness, i.e. uniformity, was measured with an atomic force microscope (AFM).

### Example 18

A 300 mm×250 mm polycarbonate plate was coated by ablating cold-pressed chitosan at the pulse repetition frequency 2.5 MHz, while the pulse energy was 5 μJ and the pulse length 19 ps. The distance between the target and the target to be coated was 25 mm. The vacuum level was 10⁻⁷ atmospheres during the coating. The coating process resulted in a partly opaque chitosan coating, with a measured thickness of 280 nm. Coarseness was in accordance with claim 1, and the surface uniformity was 10 nm when measured in the area of 1 μm². Pinholes were not found in this sample, either.

On the basis of what is specified in the invention, it is obvious for a man skilled in the art that a target and/or an object called a target can in another step of the surface treatment process serve as a substrate, and vice versa, depending on whether material is ablated therefrom (i.e. it serves as a target) or whether material is brought thereon (i.e. it serves as a substrate). At least in theory thus is possible, that the same object could function both as a substrate and as a target, according to the step of the machining/coating process.

### Ensemble of Examples on Embodiments According to the Invention Directed to a Laser Ablation Method

A laser ablation method for coating an object with one or more surfaces according to an embodiment of the invention comprises coating the object to be coated, i.e. the substrate, by ablating a target by a pulsed cold work laser, so that the uniformity of the surface deposited on the object to be coated is ±100 nm, when measured in the area of one square micrometer by an atomic force microscope (AFM).

According to an embodiment of the invention, the laser ablation method for coating an object with one or more surfaces, comprises:
holding said object at a distance from a target,
directing a pulsed cold-work laser beam to said target, thus cold ablating material from said target and producing high quality plasma,
forming, from said high-quality plasma, a coating on a surface of said object;
   wherein surface roughness of said coating is ±100 nm, when measured in the area of one square micrometer by an atomic force microscope (AFM), and wherein said coating contains less than one pinhole per 1 mm².

According to an embodiment of the invention, in the method, the uniformity of the surface deposited is ±25 nm for the object to be coated. According to an embodiment of the invention, in the method, the uniformity of the surface deposited is ±2 nm for the object to be coated. According to an embodiment of the invention, in the method, the coated surface does not include particles with a diameter larger than 1 μm. According to an embodiment of the invention, in the method, the coated surface does not include particles with a diameter larger than 100 nm. According to an embodiment of the invention, in the method, the coated surface does not include particles with a diameter larger than 25 nm.

According to an embodiment of the invention, in the method, the substrate is made of metal, metal compound, glass, stone, ceramics, synthetic polymer, semisynthetic polymer, natural polymer, paper, composite material, inorganic or organic monomeric or oligomeric material. According to an embodiment of the invention, in the method, the target is made of metal, metal compound, glass, stone, ceramics, synthetic polymer, semisynthetic polymer, natural polymer, composite material, inorganic or organic monomeric or oligomeric material.

According to an embodiment of the invention, in the method, the power of the laser apparatus is at least 10 W. According to an embodiment of the invention, in the method, the power of the laser apparatus is at least 20 W. According to an embodiment of the invention, in the method, the power of the laser apparatus is at least 50 W. According to an embodiment of the invention, in the method, the laser ablation is carried out in a vacuum with 10⁻¹-10⁻¹² atmospheres. According to an optional embodiment of the invention, in the method, the laser ablation is carried out in normal air pressure. According to an embodiment of the invention, in the method, target is ablated by a laser beam, so that material is vaporized essentially continuously from a spot of the target that was earlier distinctively non-ablated. According to an embodiment of the invention, in the method, the target is fed as lamella feed. According to an embodiment of the invention, in the method, the target is fed as film/tape feed. According to an embodiment of the invention, in the method, the target thickness is 5 μm-5 mm, advantageously 20 μm-1 mm and preferably 50 μm-200 μm. According to an embodiment of the invention, in the method, the laser beam is directed to the target through a turbine scanner. According to an embodiment of the invention, in the method, the scanning width directed to the target is 10 mm-800 mm, advantageously 100 mm-400 mm and preferably 150 mm-300 mm. According to an embodiment of the invention, in the method, the substrate is moved in a plasma plume vaporized from one or more targets by laser ablation. According to an embodiment of the invention, in the method, the distance between the target and the substrate is maintained essentially constant throughout the ablation process. According to an embodiment of the invention, in the method, the surface to be coated is formed of material that is simultaneously ablated from several targets. According to an embodiment of the invention, in the method, the surface to be coated is formed so that in a plasma plume formed of ablated material, there is brought reactive material that reacts with the ablated material contained in the plasma plume, and the resulting compound or compounds form the surface to be made on the substrate. According to an embodiment of the invention, in the method, the surface to be coated is formed so that said surface contains less than one pinhole per 1 mm², advantageously less than one pinhole per cm² and preferably it does not contain any pinholes at all in the whole coated area. According to an embodiment of the invention, in the method, the surface to be coated is formed so that the first 50% of the surface is formed so that on the created surface, there are not formed particles with a diameter larger than 1000 nm, advantageously that the size of said particles does not surpass 100 nm and preferably so that the size of said particles does not surpass 30 nm.

### Ensemble of Examples on Embodiments According to the Invention Directed to an Object Coated by the Laser Ablation Method

According to an embodiment of the invention, an object coated i.e. the substrate, by the laser ablation method with one or more surfaces, has a coating so made that the object is coated by ablating the target by a pulsed cold work laser, in which case the uniformity of the surface deposited on the coated object is ±100 nm, when measured in an area of one square micrometer with an atomic force microscope (AFM). According to an embodiment of the invention, a coated object contains in the coating less than one pinhole per 1 mm².

According to an embodiment of the invention, a coated object has uniformity of the surface ±25 nm for the coating deposited on the object. According to an embodiment of the invention, a coated object has uniformity of the surface ±2 nm for the coating deposited on the object. According to an embodiment of the invention, a coated object has such a coated surface of the object, on which there are no particles having a diameter larger than 1 μm. According to an embodiment of the invention on the coated surface of the object, there are no particles having a diameter larger than 100 nm. According to an embodiment of the invention on the coated surface of the object, there are no particles having a diameter larger than 25 mm.

According to an embodiment of the invention the coated substrate is made of metal, metal compound, glass, stone, ceramics, synthetic polymer, semisynthetic polymer, natural polymer, paper, composite material, inorganic or organic monomeric or oligomeric material. According to an embodiment of the invention the ablated target is made of metal, metal compound, glass, stone, ceramics, synthetic polymer, semisynthetic polymer, natural polymer, paper, composite material, inorganic or organic monomeric or oligomeric material. According to an embodiment of the invention the laser ablation is carried out in a vacuum with 10⁻¹-10⁻¹² atmospheres. According to an embodiment of the invention the laser ablation is carried out optionally in normal air pressure. According to an embodiment of the invention the laser beam is directed to the target through a turbine scanner. According to an embodiment of the invention the scanning width directed to the target and thereby the coating width of the substrate, i.e. the object to be coated, is 10 mm-800 mm, advantageously 100 mm-400 mm and preferably 150 mm-300 mm. According to an embodiment of the invention the substrate is moved by laser ablation in a plasma plume vaporized from one or more targets. According to an embodiment of the invention the distance between the target and the substrate is maintained essentially constant throughout the whole ablation process. According to an embodiment of the invention the surface to be coated is formed of material ablated simultaneously from several targets. According to an embodiment of the invention the surface to be coated is formed so that in the plasma plume formed of ablated material, there is brought reactive material that reacts with the material contained in the plasma plume, and the created compound or compounds form the surface to be made on the substrate. According to an embodiment of the invention the coated surface contains less than one pinhole per 1 mm², advantageously less than one pinhole per cm² and preferably it does not contain any pinholes at all in the whole coated area. According to an embodiment of the invention the coated surface is formed so that the first 50% of the surface is formed without that on the created surface there are formed particles with a diameter larger than 1000 nm, advantageously without that the size of said particles surpasses 100 nm and preferably without that the size of said particles surpasses 30 nm. According to an embodiment of the invention the target is ablated with a laser beam so that the material is vaporized essentially continuously at a spot of the target that was earlier distinctively non-ablated.

1-44. (canceled)

45. A laser ablation method for coating an object with one or more surfaces, the method comprising:
holding said object at a distance from a target;
directing a pulsed cold-work laser beam to said target, thus cold ablating material from said target and producing high quality plasma; and
forming, from said high-quality plasma, a coating on a surface of said object,
wherein surface roughness of said coating is ±100 nm, when measured in the area of one square micrometer by an atomic force microscope (AFM), and wherein said coating contains less than one pinhole per 1 mm².

46. The method according to claim 45, wherein the substrate is made of metal, metal compound, glass, stone, ceramics, synthetic polymer, semisynthetic polymer, natural polymer, paper, composite material, inorganic or organic monomeric or oligomeric material.

47. The method according to claim 45, wherein the target is made of metal, metal compound, glass, stone, ceramics, synthetic polymer, semisynthetic polymer, natural polymer, composite material, inorganic or organic monomeric or oligomeric material.

48. The method according to claim 45, wherein the laser ablation is carried out in a vacuum with 10⁻¹-10⁻¹² atmospheres.

49. The method according to claim 45, other than claim 4, wherein the laser ablation is carried out in normal air pressure.

50. The method according to claim 45, wherein target is ablated by a laser beam, so that material is vaporized essentially continuously from a spot of the target that was earlier distinctively non-ablated.

51. The method according to claim 50, wherein the target is fed as lamella feed.

52. The method according to claim 50, wherein the target is fed as film/tape feed.

53. The method according to claim 45, wherein the laser beam is directed to the target through a turbine scanner.

54. The A method according to claim 53, wherein the scanning width directed to the target is 10 mm-800 mm.

55. The method according to claim 45, wherein the substrate is moved in a plasma plume vaporized by laser ablation from one or more targets.

56. The method according to claim 45, wherein the distance between the target and the substrate is maintained essentially constant throughout the ablation process.

57. The method according to claim 45, wherein the surface to be coated is formed of material that is simultaneously ablated from several targets.

58. The method according to claim 45, wherein the surface to be coated is formed so that in a plasma plume formed of ablated material, there is brought reactive material that reacts with the ablated material contained in the plasma plume, and the resulting compound or compounds form the surface to be made on the substrate.

59. The method according to claim 45, wherein the surface to be coated is formed so that said surface contains less than one pinhole per 1 cm² and it does not contain any pinholes at all in the whole coated area.

60. The method according to claim 45, wherein the surface to be coated is formed so that the first 50% of the surface is formed on the created surface, and there are not formed particles with a diameter larger than 1000 nm.

61. An object coated by the laser ablation method of claim 45, with one or more surfaces, wherein the object, i.e. the substrate, is coated by ablating the target by a pulsed cold work laser, in which case the uniformity of the surface deposited on the coated object is ±100 nm, when measured in an area of one square micrometer with an atomic force microscope (AFM).

62. The object according to claim 61, wherein the coated substrate is made of metal, metal compound, glass, stone, ceramics, synthetic polymer, semisynthetic polymer, natural polymer, paper, composite material, inorganic or organic monomeric or oligomeric material.

63. The object according to claim 61, wherein the ablated target is made of metal, metal compound, glass, stone, ceramics, synthetic polymer, semisynthetic polymer, natural polymer, paper, composite material, inorganic or organic monomeric or oligomeric material.

64. The object according to claim 61, wherein the coated surface is formed so that the first 50% of the surface is formed without that on the created surface there are formed particles with a diameter larger than 1000 nm.
